(19) United States
(12) Patent Application Publication
(10) Pub. No.: US 2024/0194493 A1
(43) Pub. Date: Jun. 13, 2024

(54) SUBSTRATE AND METHOD FOR MANUFACTURING A SUBSTRATE

(71) Applicant: Advanced Semiconductor Engineering, Inc., Kaohsiung (TW)

(72) Inventors: Yu-Hung YEH, Kaohsiung (TW); Bing-Xiu LU, Kaohsiung (TW); Yu Lin LU, Kaohsiung (TW); Tai-Yuan HUANG, Kaohsiung (TW)

(73) Assignee: Advanced Semiconductor Engineering, Inc., Kaohsiung (TW)

(21) Appl. No.: 18/078,049

(22) Filed: Dec. 8, 2022

(51) Int. Cl. H01L 21/463; H01L 21/4763; H01L 21/66; H01L 23/14; H01L 23/544

(52) U.S. Cl. CPC H01L 21/463; H01L 21/47635; H01L 22/12; H01L 23/145; H01L 23/544

(57) ABSTRACT

A substrate includes a dielectric structure, a conductive layer, a first hole and a second hole. The conductive layer is stacked on the dielectric structure. The first hole extends from a top surface of the conductive layer and exposes the dielectric structure. The second hole is spaced apart from the first hole, extends from the top surface of the conductive layer and exposes the dielectric structure. A first depth of the first hole is substantially equal to a second depth of the second hole. An elevation of a topmost end of the first hole is different from an elevation of a topmost end of the second hole.

### BACKGROUND

### 1. Field of the Disclosure

The present disclosure relates to a substrate and a method for manufacturing a substrate, and to a substrate having a conductive layer and a method for manufacturing a substrate.

### 2. Description of the Related Art

In the manufacturing processes of substrates, blind holes need to be formed as alignment holes by, for example, machine drilling, laser drilling, sandblasting, or lithography. Machine drilling is the most suitable because of hole types, cost and unit per hour (UPH). Machine drilling generally works through a fixed Z-axis drilling stroke. However, the substrate is often uneven. Thus, the fixed Z-axis drilling stroke applied on the uneven substrate may cause some of the blind holes overdrilled and some of the blind holes underdrilled (i.e., insufficient drilling depth), resulting in a lower manufacturing yield.

### SUMMARY

In some embodiments, a method for manufacturing a substrate includes: providing a carrier with a dielectric layer and a conductive layer stacked thereon, wherein the conductive layer has a bottom surface facing the dielectric layer and a top surface; detecting the top surface of the conductive layer; and drilling since the top surface toward the dielectric layer by a predetermined distance no less than a thickness of the conductive layer.

In some embodiments, a method for manufacturing a substrate includes: providing a structure including a first conductive layer and a second conductive layer under the first conductive layer; contacting a top surface of the first conductive layer with a drilling tool to determine a first start point; drilling since the first start point; contacting a top surface of the second conductive layer with the drilling tool to determine a first end point; and stopping drilling after determining the first end point.

In some embodiments, a substrate includes a dielectric structure, a conductive layer, a first hole and a second hole. The conductive layer is stacked on the dielectric structure. The first hole extends from a top surface of the conductive layer and exposes the dielectric structure. The second hole is spaced apart from the first hole, extends from the top surface of the conductive layer and exposes the dielectric structure. A first depth of the first hole is substantially equal to a second depth of the second hole. An elevation of a topmost end of the first hole is different from an elevation of a topmost end of the second hole.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a schematic view of one or more stages of an example of a drilling method according to some embodiments of the present disclosure.

FIG. 2 illustrates a schematic view of one or more stages of an example of a drilling method according to some embodiments of the present disclosure.

FIG. 3 illustrates a schematic view of one or more stages of an example of a drilling method according to some embodiments of the present disclosure.

FIG. 4 illustrates a schematic view of one or more stages of an example of a drilling method according to some embodiments of the present disclosure.

FIG. 5 illustrates a schematic view of one or more stages of an example of a drilling method according to some embodiments of the present disclosure.

FIG. 6 illustrates an enlarged view of a region “A” in FIG. 5.

FIG. 7 illustrates a schematic view of one or more stages of an example of a drilling method according to some embodiments of the present disclosure.

FIG. 8 illustrates an enlarged view of a region “A” in FIG. 7.

FIG. 9 illustrates a schematic view of one or more stages of an example of a drilling method according to some embodiments of the present disclosure.

FIG. 10 illustrates a schematic view of one or more stages of an example of a drilling method according to some embodiments of the present disclosure.

FIG. 11 illustrates a schematic view of one or more stages of an example of a drilling method according to some embodiments of the present disclosure.

FIG. 12 illustrates an enlarged view of a region “B” in FIG. 11.

FIG. 13 illustrates a schematic view of one or more stages of an example of a drilling method according to some embodiments of the present disclosure.

FIG. 14 illustrates a schematic view of one or more stages of an example of a drilling method according to some embodiments of the present disclosure.

FIG. 15 illustrates an enlarged view of a region “C” in FIG. 14.

FIG. 16 illustrates a schematic view of one or more stages of an example of a drilling method according to some embodiments of the present disclosure.

FIG. 17 illustrates a schematic view of a drilling device according to some embodiments of the present disclosure.

FIG. 18 illustrates a schematic view of a drilling device according to some embodiments of the present disclosure.

FIG. 19 illustrates a schematic view of a drilling device according to some embodiments of the present disclosure.

FIG. 20A illustrates a schematic view of a first operation situation of the drilling tool according to some embodiments of the present disclosure.

FIG. 20B illustrates a schematic view of a second operation situation of the drilling tool according to some embodiments of the present disclosure.

FIG. 20C illustrates a schematic view of a third operation situation of the drilling tool according to some embodiments of the present disclosure.

FIG. 21A illustrates a schematic view of a fourth operation situation of the drilling tool according to some embodiments of the present disclosure.

FIG. 21B illustrates a schematic view of a fifth operation situation of the drilling tool according to some embodiments of the present disclosure.

FIG. 22 illustrates a schematic view of one or more stages of an example of a method for forming at least one conductive via in a workpiece according to some embodiments of the present disclosure.

FIG. 23 illustrates a schematic view of one or more stages of an example of a method for forming at least one conductive via in a workpiece according to some embodiments of the present disclosure.

FIG. 24 illustrates a schematic view of one or more stages of an example of a method for forming at least one conductive via in a workpiece according to some embodiments of the present disclosure.

FIG. 25 illustrates a schematic view of one or more stages of an example of a method for forming at least one conductive via in a workpiece according to some embodiments of the present disclosure.

FIG. 26 illustrates a schematic view of one or more stages of an example of a method for forming at least one conductive via in a workpiece according to some embodiments of the present disclosure.

FIG. 27 illustrates a schematic view of one or more stages of an example of a method for forming at least one conductive via in a workpiece according to some embodiments of the present disclosure.

FIG. 28 illustrates a schematic view of one or more stages of an example of a method for forming at least one conductive via in a workpiece according to some embodiments of the present disclosure.

FIG. 29 illustrates a schematic view of one or more stages of an example of a method for forming at least one conductive via in a workpiece according to some embodiments of the present disclosure.

FIG. 30 illustrates a schematic view of a substrate according to some embodiments of the present disclosure.

FIG. 31 illustrates a top view of the substrate of FIG. 30.

FIG. 32 illustrates an enlarged view of a region “D” in FIG. 30.

FIG. 33A illustrates an enlarged view of a region “E” in FIG. 30.

FIG. 33B illustrates an enlarged view of a region “F” in FIG. 30.

FIG. 34 illustrates a schematic view of one or more stages of an example of a method for manufacturing a substrate according to some embodiments of the present disclosure.

FIG. 35 illustrates a schematic view of one or more stages of an example of a method for manufacturing a substrate according to some embodiments of the present disclosure.

FIG. 36 illustrates a schematic view of one or more stages of an example of a method for manufacturing a substrate according to some embodiments of the present disclosure.

FIG. 37 illustrates a schematic view of one or more stages of an example of a method for manufacturing a substrate according to some embodiments of the present disclosure.

FIG. 38 illustrates a schematic view of one or more stages of an example of a method for manufacturing a substrate according to some embodiments of the present disclosure.

FIG. 39 illustrates a schematic view of one or more stages of an example of a method for manufacturing a substrate according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

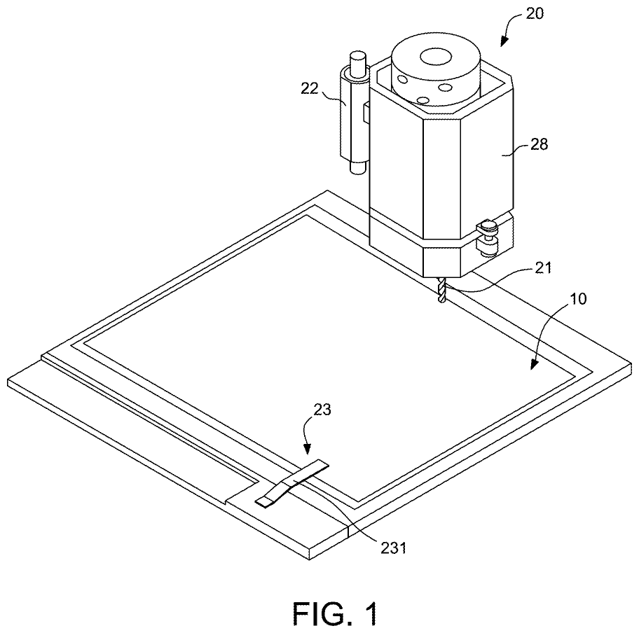

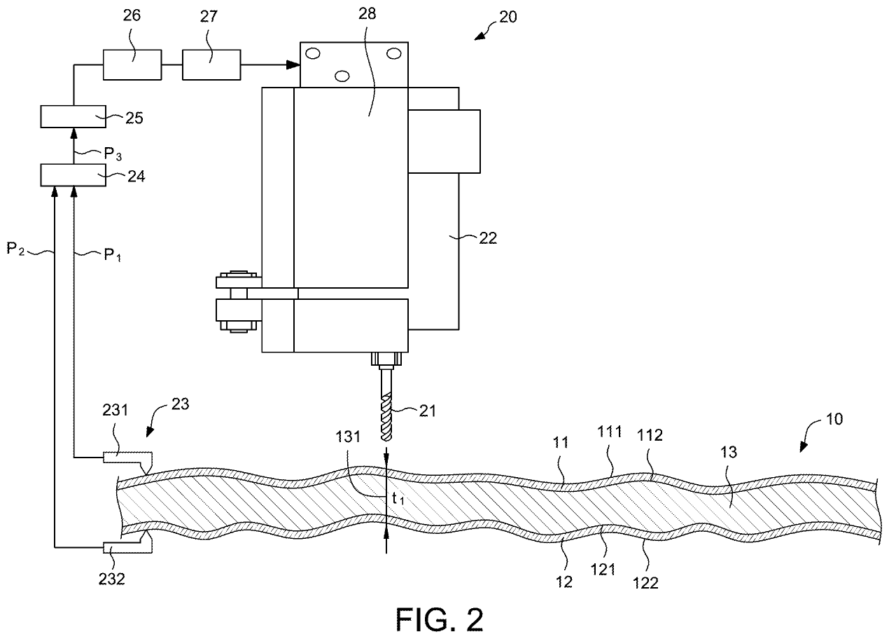

FIG. 1 through FIG. 9 illustrate a drilling method according to some embodiments of the present disclosure. Referring to FIG. 1 and FIG. 2, a substrate 10 and a drilling device 20 are provided. FIG. 1 may be a schematic perspective view of the substrate 10 and the drilling device 20 in accordance with some embodiments of the present disclosure. FIG. 2 may be a schematic cross-sectional view of the substrate 10 and a side view the drilling device 20 in accordance with some embodiments of the present disclosure. The drilling device 20 may be configured to drill the substrate 10.

The substrate 10 may be a structure or an assembly structure. The substrate 10 may be, for example, a laminated substrate or an embedded substrate. The substrate 10 may include a first conductive layer 11, a second conductive layer 12 and a dielectric structure 13. The first conductive layer 11 may be, for example, a metal layer or a circuit layer. In some embodiments, the first conductive layer 11 may include conductive polymer such as polyacetylene. The first conductive layer 11 has a first conductive surface 111 and a second conductive surface 112. The first conductive surface 111 of the first conductive layer 11 may be a top surface of the substrate 10. The second conductive surface 112 is opposite to the first conductive surface 111. The second conductive layer 12 may be longitudinally spaced apart from the first conductive layer 11. The second conductive layer 12 may be disposed under the first conductive layer 11. The second conductive layer 12 may be, for example, a metal layer or a circuit layer. In some embodiments, the second conductive layer 12 may include conductive polymer such as polyacetylene. The second conductive layer 12 has a first conductive surface 121 and a second conductive surface 122. The second conductive surface 122 of the second conductive layer 12 may be a bottom surface of the substrate 10. The first conductive surface 121 of the second conductive layer 12 may be longitudinally spaced apart from the first conductive surface 111 of the first conductive layer 11. The second conductive surface 122 is opposite to the first conductive surface 121. The dielectric structure 13 may be disposed between the first conductive layer 11 and the second conductive layer 12. For example, the dielectric structure 13 may be made of a cured photoimageable dielectric (PID) material such as epoxy or polyimide (PI) including photoinitiators. For example, the dielectric structure 13 may include a homogeneous material. For example, the material of the dielectric structure 13 may include epoxy type FR5, FR4, Bismaleimide triazine (BT), print circuit board (PCB) material, Ajinomoto build-up film (ABF) or other suitable materials. In some embodiments, the first conductive layer 11 may be laminated on a top surface of the dielectric structure 13, and the second conductive layer 12 may be laminated on a bottom surface of the dielectric structure 13 to form the substrate 10.

In some embodiments, as shown in FIG. 2, the first conductive surface 111 of the first conductive layer 11 and the first conductive surface 121 of the second conductive layer 12 may be uneven surfaces. The second conductive surface 112 of the first conductive layer 11 and the second conductive surface 122 of the second conductive layer 12 may be uneven surfaces. Alternatively, the first conductive surface 111 of the first conductive layer 11 may be non-parallel with the first conductive surface 121 and the second conductive surface 122 of the second conductive layer 12. The second conductive surface 112 of the first conductive layer 11 may be non-parallel with the first conductive surface 121 and the second conductive surface 122 of the second conductive layer 12. The top surface of the dielectric structure 13 may be non-parallel with the bottom surface of the dielectric structure 13. Thus, the substrate 10 may have a non-uniform thickness or an inconsistent thickness. However, in other embodiments, the substrate 10 may have a uniform thickness or a consistent thickness, but have a wavy structure.

Referring to FIG. 1 and FIG. 2 again, the drilling device 20 may be disposed above the first conductive surface 111 of the first conductive layer 11 of the substrate 10. The drilling device 20 may be, for example, a computer numerical control (CNC) drilling device or a numerical control (NC) drilling device. The drilling device 20 may include a device body 28, a drilling tool 21, a current source 22, a conductive element 23, a signal receiver 24 (e.g., a signal converter), a control unit 25, a record unit 26, and a data processing unit 27. The drilling tool 21 (e.g., a drill bit) may be disposed at a bottom of the device body 28 and configured to drill the substrate 10. The drilling tool 21 (e.g., a drill bit) may be disposed above or corresponding to a first portion 131 of the substrate 10. The first portion 131 of the substrate 10 may have a first thickness t₁.

The current source 22 may be electrically connected to the drilling tool 21 and configured to generate or provide an electric signal to stop the drilling process of the drilling tool 21. The conductive element 23 may be configured to contact the substrate 10 (e.g., the first conductive surface 111 of the first conductive layer 11 and the second conductive surface 122 of the second conductive layer 12). The conductive element 23 may be a conductive pressing element, and may include a first conductive element 231 (e.g., a first conductive pressing element) and a second conductive element 232 (e.g., a second conductive pressing element). The first conductive element 231 may physically connect and electrically connect the first conductive surface 111 of the first conductive layer 11 of the substrate 10. The second conductive element 232 may physically connect and electrically connect the second conductive surface 122 of the second conductive layer 12 of the substrate 10. Thus, the current source 22 may be electrically connected to the drilling tool 21 through the conductive element 23 (including the first conductive element 231 and the second conductive element 232) and the substrate 10 (e.g., the first conductive surface 111 of the first conductive layer 11 and the first conductive surface 121 of the second conductive layer 12).

The signal receiver 24 may be electrically connected to the conductive element 23 (including the first conductive element 231 and the second conductive element 232). For example, the signal receiver 24 may be electrically connected to the first conductive element 231 and the second conductive element 232 through a first electrical path P₁ and a second electrical path P₂, respectively. However, in other embodiments, the first electrical path P₁ and the second electrical path P₂ may be a same electrical path. The signal receiver 24 may be configured to convert a waveform of the electric signal (transmitted form the first electrical path P₁ and the second electrical path P₂) from a triangle wave or a sine wave to a square wave. That is, the signal receiver 24 may be configured to process the electric signal and filter noise so as to obtain a distinguishable signal.

The control unit 25 may be a computer numerical control (CNC) unit or a numerical control (NC) unit. The control unit 25 may be electrically connected to the signal receiver 24 through a third electrical path P₃. The control unit 25 may be configured to control the actions of the drilling tool 21 according to the electric signal from the third electrical path P₃. The record unit 26 may be electrically connected to the control unit 25 and the current source 22, and configured to record the elevations of position points (e.g., the start point Sp and the end point Ep as stated below) of drilling. The elevation of a specific point may be a vertical distance between the specific point and a horizontal reference plane. The data processing unit 27 may be electrically connected to the record unit 26 and configured to determine a flatness of the substrate 10 according to the elevations of position points of drilling recorded in the record unit 26.

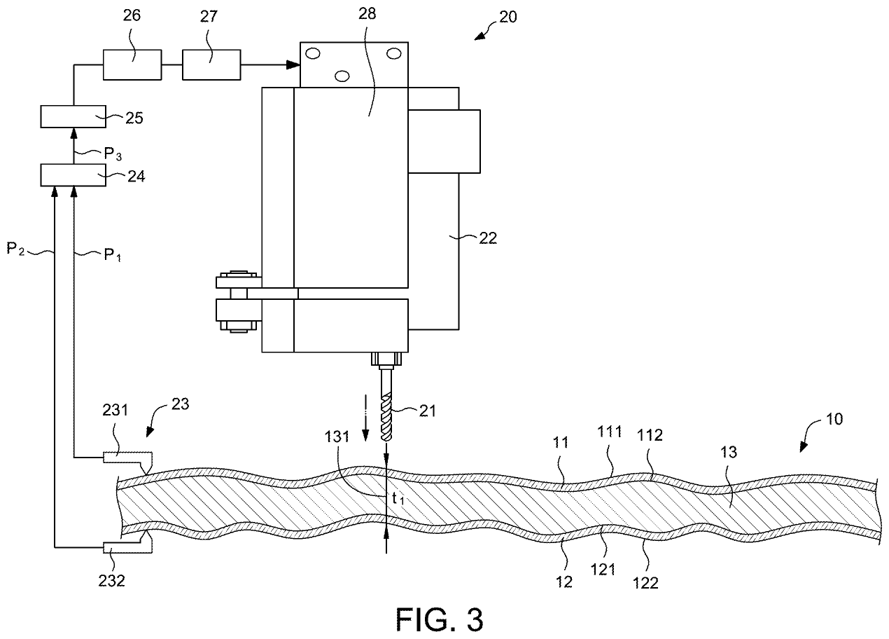

Referring to FIG. 3, the drilling tool 21 is moved toward the substrate 10.

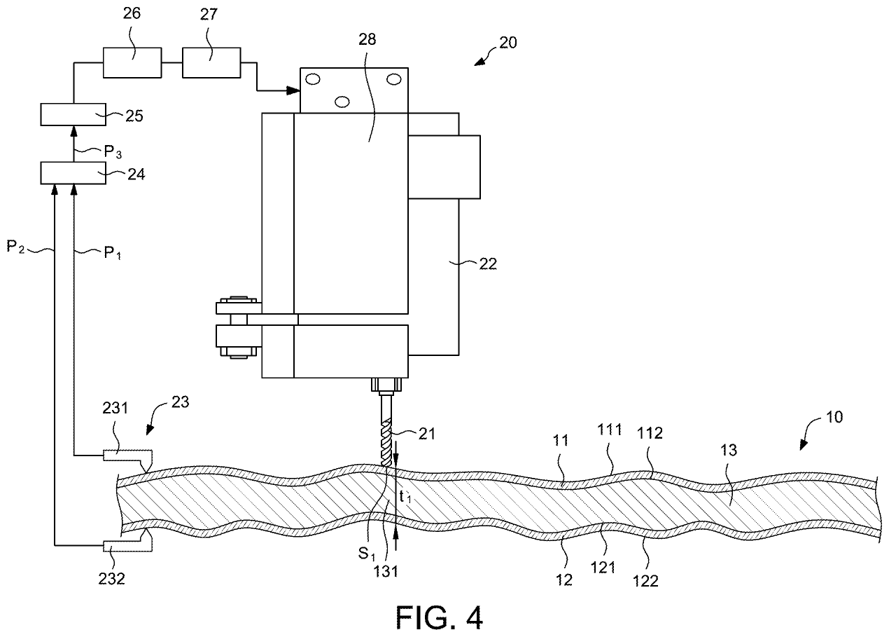

Referring to FIG. 4, the drilling tool 21 is moved to contact the substrate 10. In some embodiments, the top surface 111 of the first conductive layer 11 may be contacted with the drilling tool 21 so as to determine a first start point S₁. The first start point S₁ is defined through a first electric signal (or a first signal) generated by the drilling tool 21 contacting the first conductive surface 111 of the first conductive layer 11. In some embodiments, the record unit 26 and the data processing unit 27 may receive the first signal when the drilling tool 27 contacts the first conductive layer 11 to determine the first start point S₁. Meanwhile, a first electrical loop is formed through electrical connections of the drilling tool 21, the first conductive surface 111 of the first conductive layer 11, the first conductive element 231 and the current source 22. That is, the first electrical loop is formed when the drilling tool 21 contacts the first conductive layer 11. In some embodiments, the first electrical loop may generate the first electric signal. In some embodiments, when the first electrical loop and the first electric signal are generated, the drilling tool 21 starts to rotate so as to start the drilling process or drilling operation. In some embodiments, the flatness of the substrate 10 may be estimated by a variation of a plurality of first start points S₁ at different locations of the substrate 10. For example, the flatness of the substrate 10 may be determined by comparing the elevations of the first start points S₁ at different locations of the substrate 10.

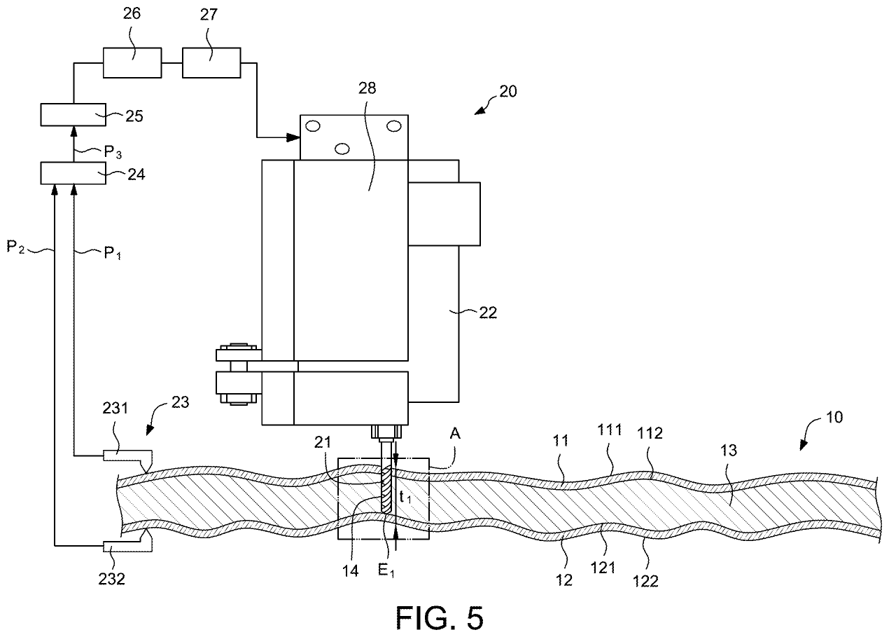

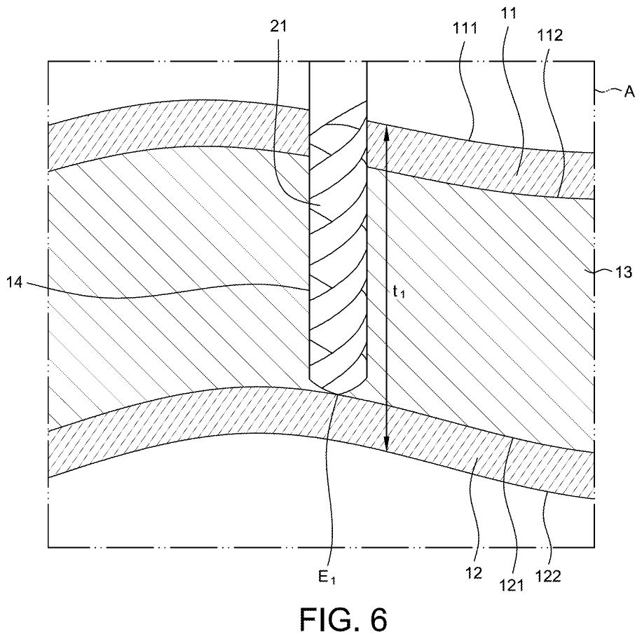

Referring to FIG. 5 and FIG. 6, wherein FIG. 6 illustrates an enlarged view of a region “A” in FIG. 5, the drilling tool 21 is moved downward to penetrate through the first conductive layer 11 and the dielectric structure 13, and contact the first conductive surface 121 of the second conductive layer 12. The first conductive layer 11 may be drilled since the first start point S₁. The first portion 131 (e.g., a portion of the first conductive layer 11 and a portion of the dielectric structure 13) of the substrate 10 of FIG. 4 may be removed through the drilling tool 21. A first end point E₁ is defined through a second electric signal (or a second signal) generated by the drilling tool 21 contacting the first conductive surface 121 of the second conductive layer 12. That is, the top surface 121 of the second conductive layer 12 may be contacted with the drilling tool 21 so as to determine the first end point E₁. In some embodiments, the record unit 26 and the data processing unit 27 may receive the second signal when the drilling tool 27 contacts the second conductive layer 12 to determine the first end point E₁. The first end point E₁ is located on the first conductive surface 121 of the second conductive layer 12. Meanwhile, a second electrical loop is formed through electrical connections of the drilling tool 21, the second conductive surface 122 of the second conductive layer 12, the second conductive element 232 and the current source 22. That is, the second electrical loop is formed when the drilling tool 21 contacts the second conductive layer 12. In some embodiments, the second electrical loop may generate the second electric signal. In some embodiments, the second electric signal is generated after the first electric signal disappears. Thus, there is a time difference between the second electric signal and the first electric signal. In some embodiments, the second electric signal may be generated when the first electric signal does not disappear. In some embodiments, when the second electrical loop and the second electric signal are generated, the drilling tool 21 may stop to rotate and may be removed from the substrate 10 so as to stop the drilling process or drilling operation. Thus, the drilling process or the drilling operation of the drilling tool 21 may stop at the first end point E₁ of second conductive layer 12. That is, the drilling process or drilling operation may be stopped after determining the first end point E₁.

In some embodiments, the flatness or the thickness uniformity of the substrate 10 may be estimated by a variation of a plurality of first end points E₁ at different locations of the substrate 10. For example, the first thickness t₁ of the first portion 131 of the substrate 10 may be substantially determined by a difference between the elevation of the first start point S₁ and the elevation of the first end point E₁. Thus, the thickness uniformity of the substrate 10 may be determined by comparing the first thickness t₁ at different locations of the substrate 10.

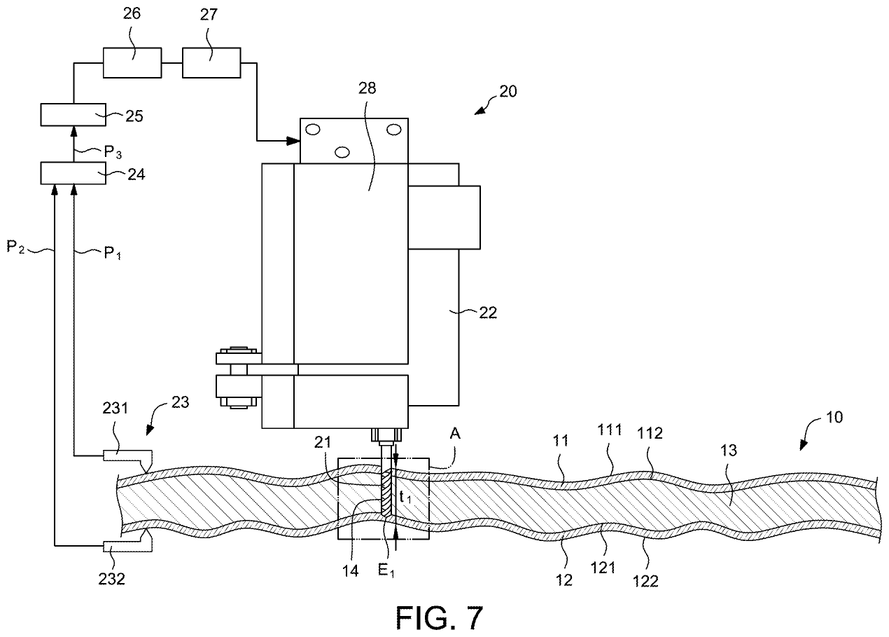

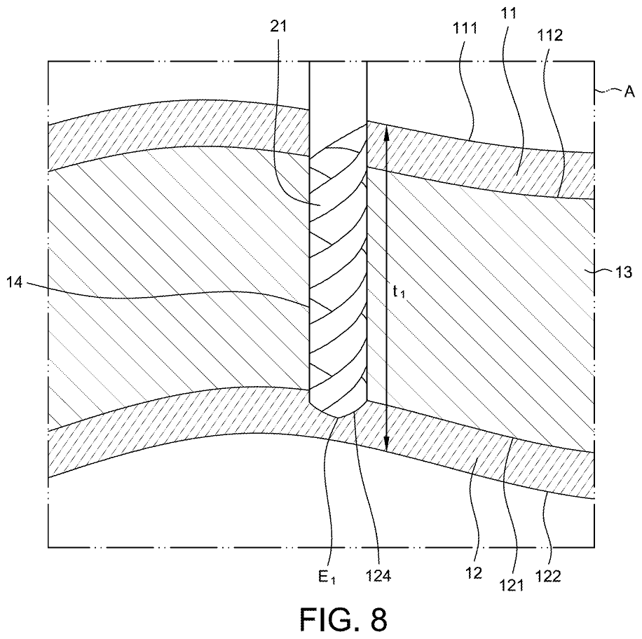

Referring to FIG. 7 and FIG. 8, wherein FIG. 8 illustrates an enlarged view of a region “A” in FIG. 7, the drilling tool 21 may be further moved downward to remove a portion of the second conductive layer 12, including the first conductive surface 121 of the second conductive layer 12. Thus, a first dimple 124 may be formed on the first conductive surface 121 of the second conductive layer 12. The first dimple 124 may be recessed from the first conductive surface 121 of the second conductive layer 12. The first end point E₁ may be a bottom end of the first dimple 124. In some embodiments, a first drilling depth (or stroke) of the drilling tool 21 may be determined according to a distance between the first start point S₁ and the first end point E₁. For example, the first drilling depth may be substantially equal to a value that subtracts a thickness of the second conductive layer 12 corresponding to the first portion 131 of the substrate 10 from the first thickness t₁ of the first portion 131 of the substrate 10. In some embodiments, the thickness uniformity of the substrate 10 may also be estimated by a variation of a plurality of first drilling depths of the drilling tool 21 at different locations for forming different holes of the substrate 10.

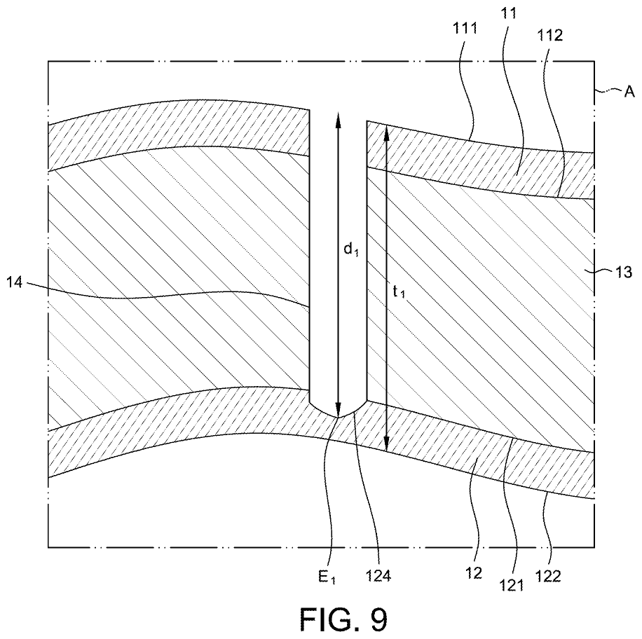

Referring to FIG. 9, the drilling device 20 is moved upward so that the drilling tool 21 is removed from the substrate 10 so as to form a first hole 14 in the substrate 10. The first hole 14 may stop at the second conductive layer 12. That is, a portion of the second conductive layer 12 may be exposed in the first hole 14. The first hole 14 may include the first dimple 124. The first hole 14 may be a blind hole that does not extend through the second conductive layer 12. The first hole 14 may have a first depth d₁. The first depth d₁ of the first hole 14 may be substantially equal to the first drilling depth (or stroke) of the drilling tool 21.

As shown in the embodiment illustrated in FIG. 1 through FIG. 9, the first drilling depth (or stroke) of the drilling tool 21 can be precisely and immediately determined through the first start point S₁ defined by the first electric signal and the first end point E₁ defined by the second electric signal. Such design may prevent the drilling tool 21 from overdrilling or underdrilling, leading to an improved manufacturing yield. Thus, even if the substrate 10 has a non-uniform thickness or an inconsistent thickness, the first hole 14 may be formed precisely to extend through the first conductive layer 11 and the dielectric structure 13 completely and to expose a portion of the second conductive layer 12. Alternatively, although the first conductive surface 111 of the first conductive layer 11 of the substrate 10 is uneven or non-flat, the first hole 14 may still be formed precisely to terminate at the second conductive layer 12 and expose a portion of the second conductive layer 12.

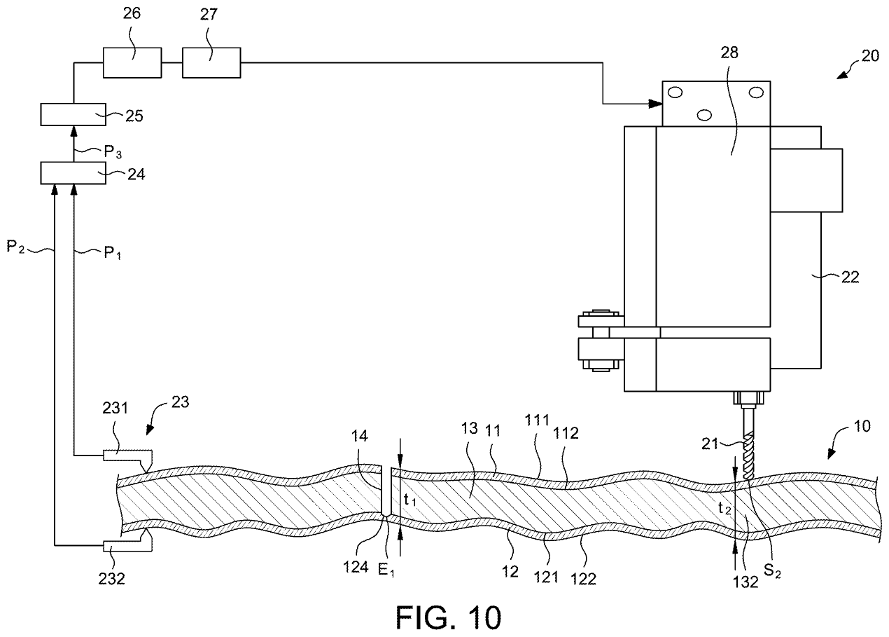

FIG. 10 through FIG. 13 illustrate a drilling method according to some embodiments of the present disclosure. The initial stages of the illustrated process are the same as, or similar to, the stages illustrated in FIG. 1 and FIG. 9. FIG. 10 depicts a stage subsequent to that depicted in FIG. 9.

Referring to FIG. 10, the drilling device 20 and the drilling tool 21 are moved to a position above or corresponding to a second portion 132 of the substrate 10. The second portion 132 of the substrate 10 may have a second thickness t₂. The second thickness t₂ of the second portion 132 of the substrate 10 may be different from the first thickness t₁ (FIG. 4) of the first portion 131 of the substrate 10. For example, a thickness of a second portion of the dielectric structure 13 of the second portion 132 of the substrate 10 may be different from a thickness of a first portion of the dielectric structure 13 of the first portion 131 of the substrate 10. Then, the drilling tool 21 is moved downward to contact the substrate 10. In some embodiments, the top surface 111 of the first conductive layer 11 may be contacted with the drilling tool 21 so as to determine a second start point S₂. The second start point S₂ is defined through a third electric signal generated by the drilling tool 21 contacting the first conductive surface 111 of the first conductive layer 11. The elevation of the second start point S₂ may be same as or different form the elevation of the first start point S₁. Meanwhile, a third electrical loop is formed through electrical connections of the drilling tool 21, the first conductive surface 111 of the first conductive layer 11, the first conductive element 231 and the current source 22. In some embodiments, the third electrical loop may generate the third electric signal. In some embodiments, the third electrical loop and the third electric signal may be same as or similar to the first electrical loop and the first electric signal, respectively. In some embodiments, when the third electrical loop and the third electric signal are generated, the drilling tool 21 starts to rotate so as to start the drilling process or drilling operation. In some embodiments, the flatness of the substrate 10 may be estimated by a variation of a plurality of second start point S₂ at different locations of the substrate 10. For example, the flatness of the substrate 10 may be determined by comparing an elevation of the first start point S₁ and an elevation of the second start point S₂. The flatness of the structure 10 (substrate 10) may be estimated from the variation between the elevation of the first start point S₁ and the elevation of the second start point S₂.

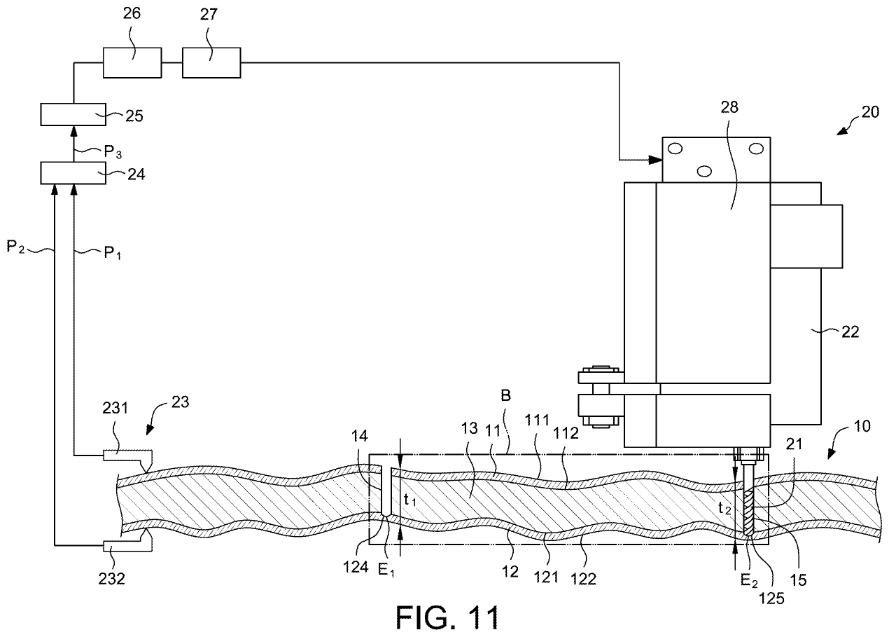

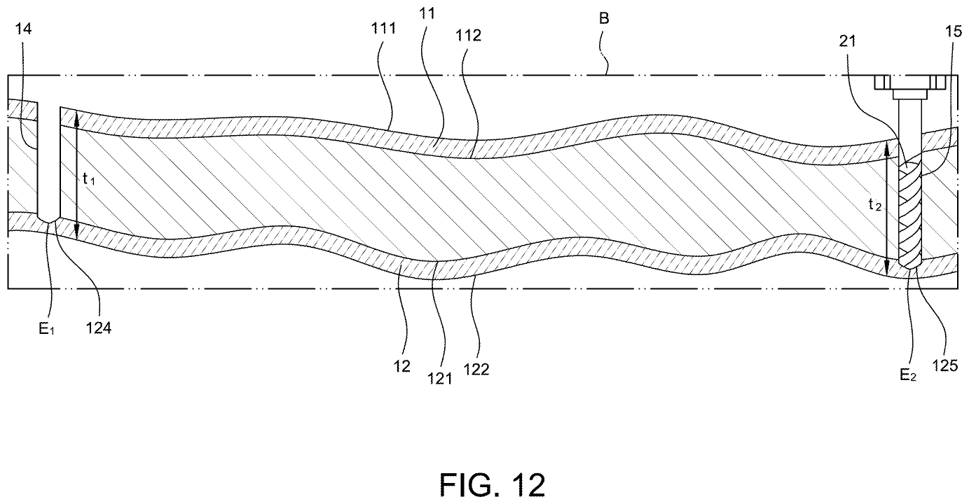

Referring to FIG. 11 and FIG. 12, wherein FIG. 12 illustrates an enlarged view of a region “B” in FIG. 11, the drilling tool 21 is moved downward to penetrate through the first conductive layer 11 and the dielectric structure 13. The first conductive layer 11 may be drilled since the second start point S₂. A second end point E₂ is defined through a fourth electric signal generated by the drilling tool 21 contacting the first conductive surface 121 of the second conductive layer 12. That is, the top surface 121 of the second conductive layer 12 may be contacted with the drilling tool 21 so as to determine the second end point E₂. The second end point E₂ is located on the first conductive surface 121 of the second conductive layer 12. The elevation of the second end point E₂ may be same as or different form the elevation of the first end point E₁. Meanwhile, a fourth electrical loop is formed through electrical connections of the drilling tool 21, the first conductive surface 121 of the second conductive layer 12, the second conductive element 232 and the current source 22. In some embodiments, the fourth electrical loop may generate the fourth electric signal. In some embodiments, the fourth electrical loop and the fourth electric signal may be same as or similar to the second electrical loop and the second electric signal, respectively. In addition, the fourth electric signal is generated after the third electric signal disappears. Thus, there is a time difference between the fourth electric signal and the third electric signal. In some embodiments, the fourth electric signal may be generated when the third electric signal does not disappear. In some embodiments, when the fourth electrical loop and the fourth electric signal are generated, the drilling tool 21 may stop to rotate so as to stop the drilling process or drilling operation. Thus, the drilling process or the drilling operation of the drilling tool 21 may stop at the second end point E₂ of second conductive layer 12. That is, the drilling process or drilling operation may be stopped after determining the second end point E₂.

In some embodiments, the flatness or the thickness uniformity of the substrate 10 may be estimated by a variation of a plurality of second end points E₂ at different locations of the substrate 10. For example, the second thickness t₂ of the second portion 132 of the substrate 10 may be substantially determined by a difference between the elevation of the second start point S₂ and the elevation of the second end point E₂. Thus, the thickness uniformity of the substrate 10 may be determined by comparing the first thickness t₁ and the second thickness t₂.

The second portion 132 (e.g., a portion of the first conductive layer 11 and a portion of the dielectric structure 13) of the substrate 10 of FIG. 10 may be removed through the drilling tool 21. In some embodiments, a portion of the second conductive layer 12 may be removed so as to form a second dimple 125 on the first conductive surface 121 of the second conductive layer 12. The second dimple 125 may be recessed from the first conductive surface 121 of the second conductive layer 12. An elevation of the second dimple 125 may be same as or different from an elevation of the first dimple 124. In some embodiments, a second drilling depth (or stroke) of the drilling tool 21 may be determined according to a distance between the second start point S₂ and the second end point E₂. For example, the second drilling depth may be substantially equal to a value that subtracts a thickness of the second conductive layer 12 corresponding to the second portion 132 of the substrate 10 from the second thickness t₂ of the second portion 132 of the substrate 10. In some embodiments, the thickness uniformity of the substrate 10 may also be estimated by a variation of a plurality of second drilling depths of the drilling tool 21 at different locations for forming different holes of the substrate 10. In some embodiments, the second drilling depth may be equal to or different from the first drilling depth.

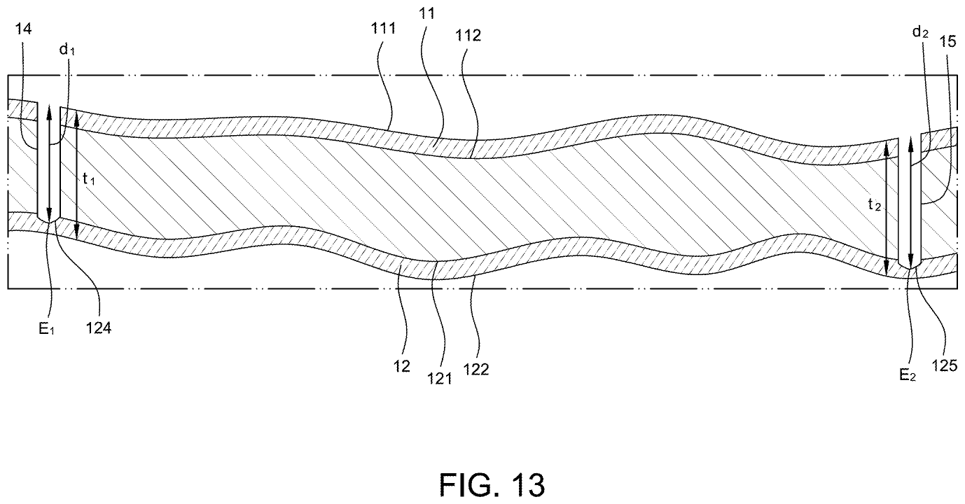

Referring to FIG. 13, the drilling device 20 is moved upward so that the drilling tool 21 is removed from the substrate 10 so as to form a second hole 15 in the substrate 10. The second hole 15 may stop at the second conductive layer 12. That is, a portion of the second conductive layer 12 may be exposed in the second hole 15. The second hole 15 may include the second dimple 125. The second hole 15 may be a blind hole that does not extend through the second conductive layer 12. The second hole 15 may have a second depth d₂. The second depth d₂ of the second hole 15 may be substantially equal to the second drilling depth (or stroke) of the drilling tool 21. In some embodiments, the second depth d₂ of the second hole 15 may be equal to or different from the first depth d₁ of the first hole 14. A top end of the second hole 15 may be not level with a top end of the first hole 14. A bottom end of the second hole 15 may be not level with a bottom end of the first hole 14.

As shown in the embodiment illustrated in FIG. 10 through FIG. 13, the second drilling depth (or stroke) of the drilling tool 21 can be precisely and immediately determined through the second start point S₂ defined by the third electric signal. The second end point E₂ defined by the fourth electric signal may prevent the drilling tool 21 from overdrilling or underdrilling, leading to an increased manufacturing yield. Thus, even if the substrate 10 has a non-uniform thickness or an inconsistent thickness, the second hole 15 may be formed precisely to extend through the first conductive layer 11 and the dielectric structure 13 completely and to expose a portion of the second conductive layer 12. Alternatively, although the depth of the second hole 15 may be different from the depth of the first hole 14, both the first hole 14 and the second hole 15 may still be formed precisely to terminate at the second conductive layer 12 and expose a portion of the second conductive layer 12.

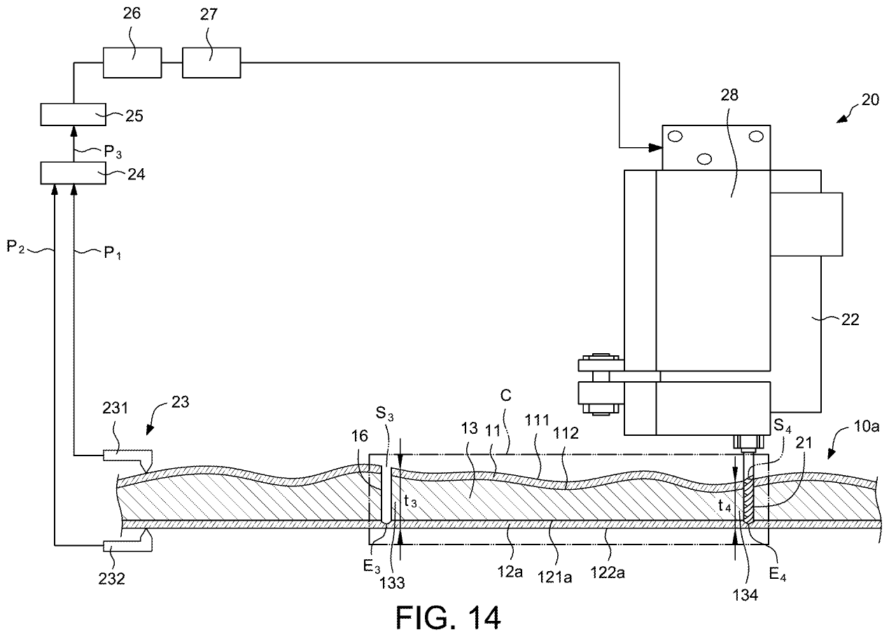

FIG. 14 through FIG. 16 illustrate a drilling method according to some embodiments of the present disclosure. The initial stages of the illustrated process are similar to the stages illustrated in FIG. 1 and FIG. 9, except for the structure of the substrate 10a. The substrate 10a of FIG. 14 is similar to the substrate 10 of FIG. 2, except for the structure of the second conductive layer 12a. Both the first conductive surface 121a and the second conductive surface 122a of the second conductive layer 12a are even surfaces and flat surfaces, and they are parallel with each other. The substrate 10a may have a third portion 133 (or a first portion) and a fourth portion 134 (or a second portion). The third portion 133 may have a third thickness t₃ (or a first thickness). The fourth portion 134 may have a fourth thickness t₄ (or a second thickness). The third thickness t₃ may be equal to or different from the fourth thickness t₄.

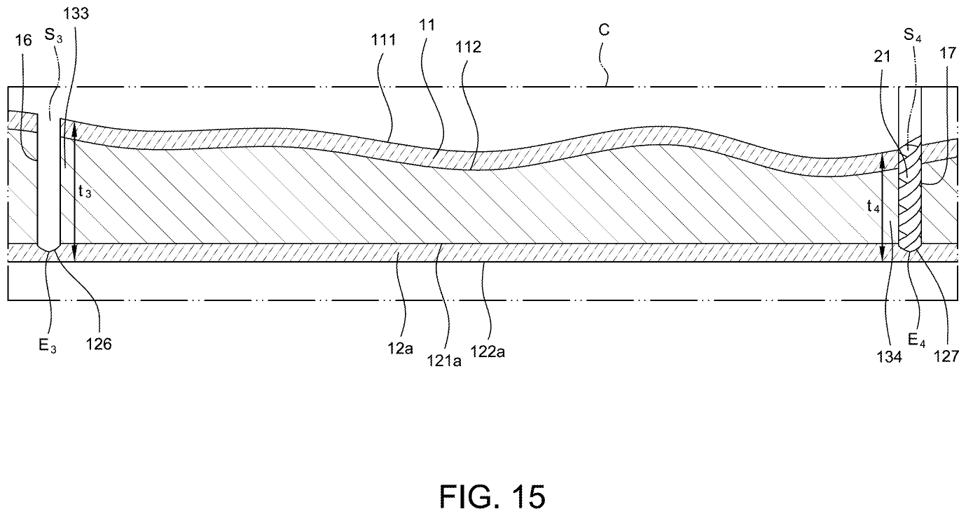

Referring to FIG. 14 and FIG. 15, wherein FIG. 15 illustrates an enlarged view of a region “C” in FIG. 14, a third hole 16 (or a first hole) may be formed at the position corresponding to the third portion 133. The process for forming the third hole 16 may be same as or similar to the process for forming the first hole 14 as shown in FIG. 1 through FIG. 9. For example, the third hole 16 may be formed by drilling the substrate 10a from a third start point S₃ (or first start point) on the first conductive surface 111 of the first conductive layer 11 to a third end point E₃ (or first end point) on the first conductive surface 121a of the second conductive layer 12a. Such drilling process may be accomplished by using the drilling tool 21 of the drilling device 20. The third hole 16 may include a third dimple 126 (or a first dimple) recessed from the first conductive surface 121a of the second conductive layer 12a. The third start point S₃ is defined through a fifth electric signal or a fifth electrical loop generated by the drilling tool 21 contacting the first conductive surface 111 of the first conductive layer 11. In addition, the third end point E₃ is defined through a sixth electric signal generated by the drilling tool 21 contacting the first conductive surface 121a of the second conductive layer 12a. The third end point E₃ is located on the first conductive surface 121a of the second conductive layer 12a.

Then, the drilling device 20 and the drilling tool 21 are moved to a position above or corresponding to the fourth portion 134 of the substrate 10. Then, the drilling tool 21 is moved downward to form a fourth hole 17 (or a second hole) in the substrate 10a. The fourth hole 17 may be formed at the position corresponding to the fourth portion 134. The process for forming the fourth hole 17 may be same as or similar to the process for forming the second hole 15 as shown in FIG. 10 through FIG. 13. For example, the fourth hole 17 may be formed by drilling the substrate 10a from a fourth start point S₄ (or second start point) on the first conductive surface 111 of the first conductive layer 11 to a fourth end point E₄ (or second end point) on the first conductive surface 121a of the second conductive layer 12a. The fourth hole 17 may include a fourth dimple 127 (or a second dimple) recessed from the first conductive surface 121a of the second conductive layer 12a. The fourth start point S₄ is defined through a seventh electric signal or a seventh electrical loop generated by the drilling tool 21 contacting the first conductive surface 111 of the first conductive layer 11. The elevation of the fourth start point S₄ may be same as or different form the elevation of the third start point S₃. In addition, the fourth end point E₄ is defined through an eighth electric signal generated by the drilling tool 21 contacting the first conductive surface 121a of the second conductive layer 12a. The fourth end point E₄ is located on the first conductive surface 121a of the second conductive layer 12a. The elevation of the fourth end point E₄ may be same as the elevation of the third end point E₃. An elevation of the fourth dimple 127 may be same as or different from an elevation of the third dimple 126.

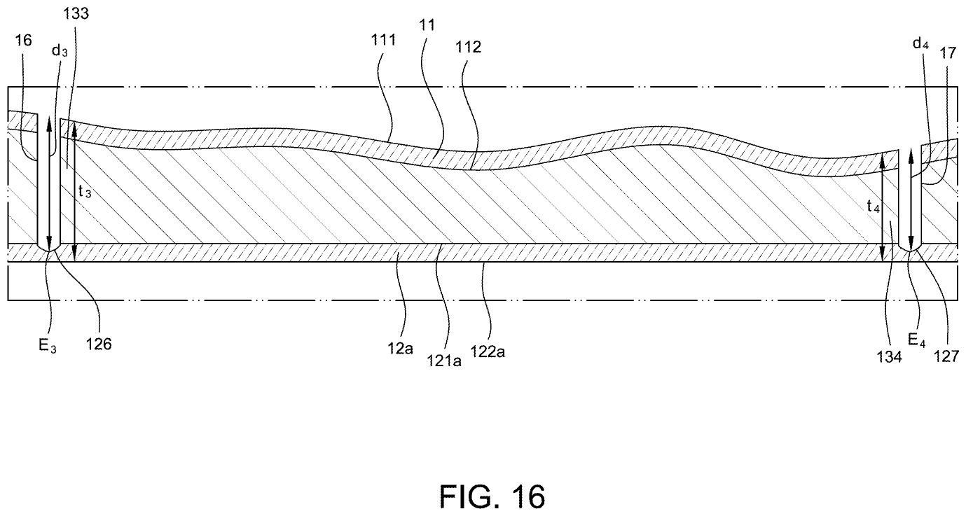

Referring to FIG. 16, the drilling device 20 is moved upward so that the drilling tool 21 is removed from the substrate 10a. In some embodiments, a fourth depth de of the fourth hole 17 may be equal to or different from the third depth d₃ of the third hole 16.

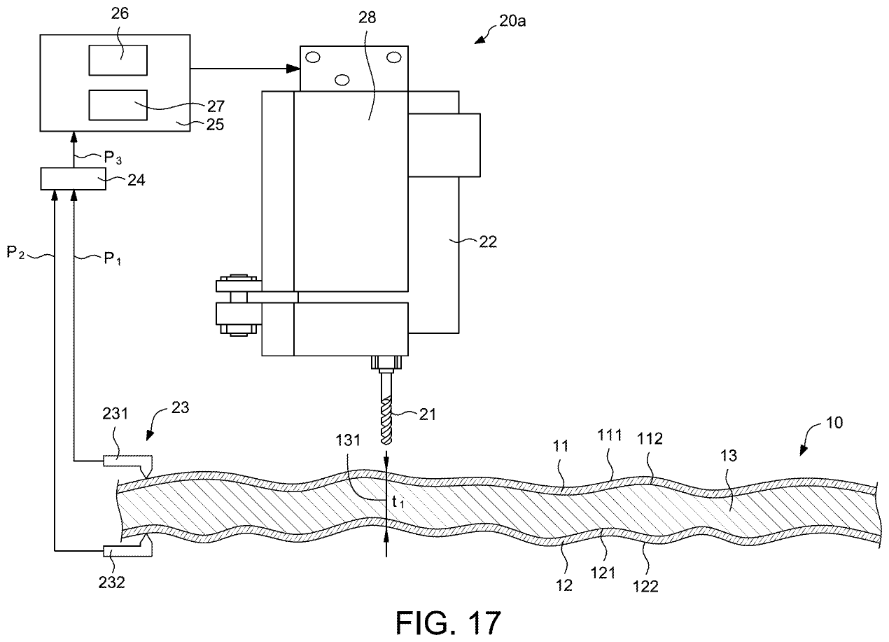

FIG. 17 illustrates a schematic view of a drilling device 20a according to some embodiments of the present disclosure. The drilling device 20a of FIG. 17 may be same as the drilling device 20 of FIG. 2, except that the record unit 26 and the data processing unit 27 are included in the control unit 25.

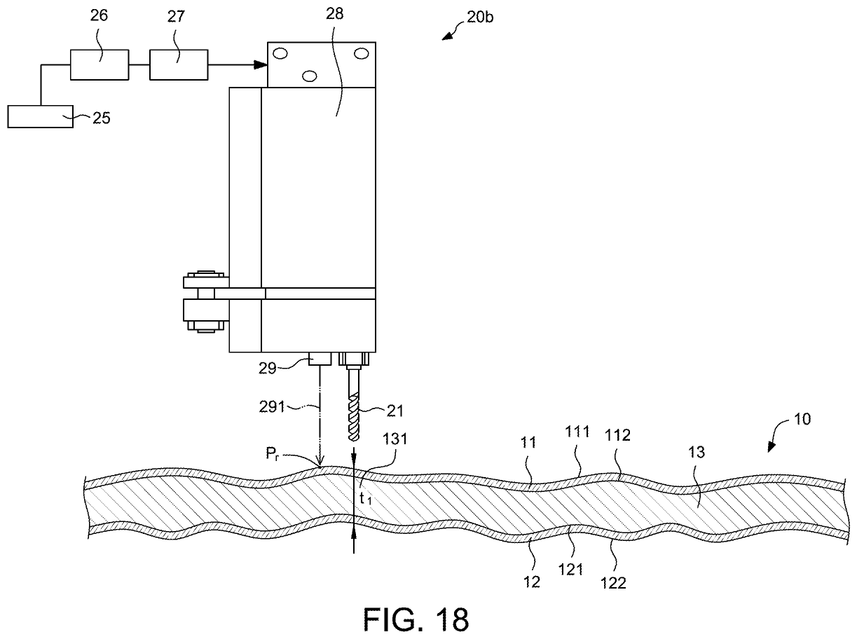

FIG. 18 illustrates a schematic view of a drilling device 20b according to some embodiments of the present disclosure. The drilling device 20b of FIG. 18 may be same as the drilling device 20 of FIG. 2, except that the current source 22, the conductive element 23 and the signal receiver 24 of FIG. 2 are omitted, and a distance measurement device 29 is further included. The distance measurement device 29 may be a laser rangefinder. The distance measurement device 29 may be attached to the device body 28, and may be very close to the drilling tool 21. The distance measurement device 29 may emit a laser beam to the first conductive surface 111 of the first conductive layer 11 to determine an elevation of the reference point Pᵣ. The position of the reference point Pᵣ is very close to the first start point S₁ (FIG. 4). In some embodiments, the reference point Pᵣ may be considered as the first start point St. Thus, the elevation of the reference point Pᵣ (or the first start point S₁) may be determined by optical means, and may be recorded in the record unit 26.

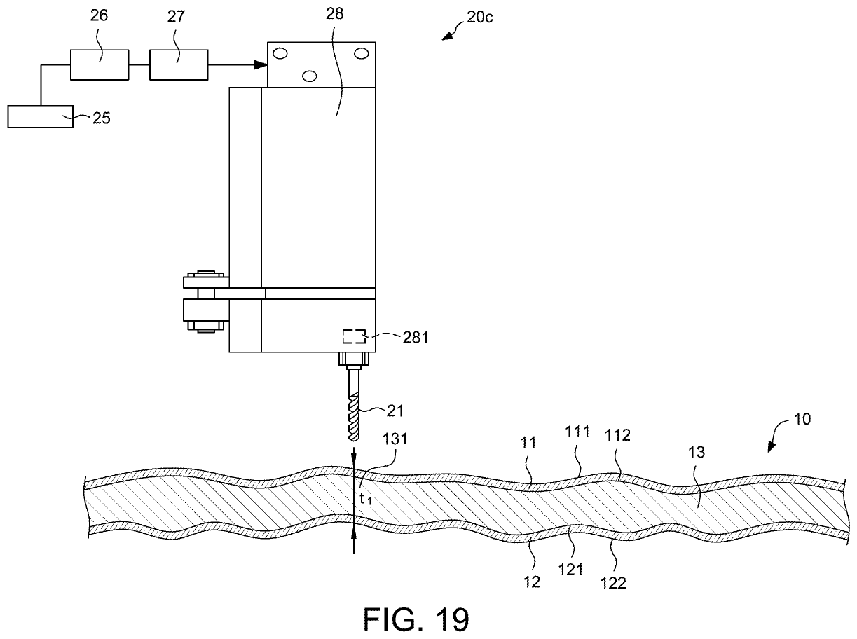

FIG. 19 illustrates a schematic view of a drilling device 20c according to some embodiments of the present disclosure. The drilling device 20c of FIG. 19 may be same as the drilling device 20 of FIG. 2, except that the current source 22, the conductive element 23 and the signal receiver 24 of FIG. 2 are omitted, and a force sensor 281 is further included. The force sensor 281 may be a load measuring device such as a load cell, and may be disposed in the device body 28. The force sensor 281 may be connected to the drilling tool 21. When the drilling tool 21 moves downward to contact the first conductive surface 111 of the first conductive layer 11 at the first start point S₁ (FIG. 4), the force sensor 281 may sense a reaction force from the drilling tool 21 and determine an elevation of the first start point S₁ (FIG. 4). Thus, the elevation of the first start point S₁ may be determined by physical contact, and may be recorded in the record unit 26.

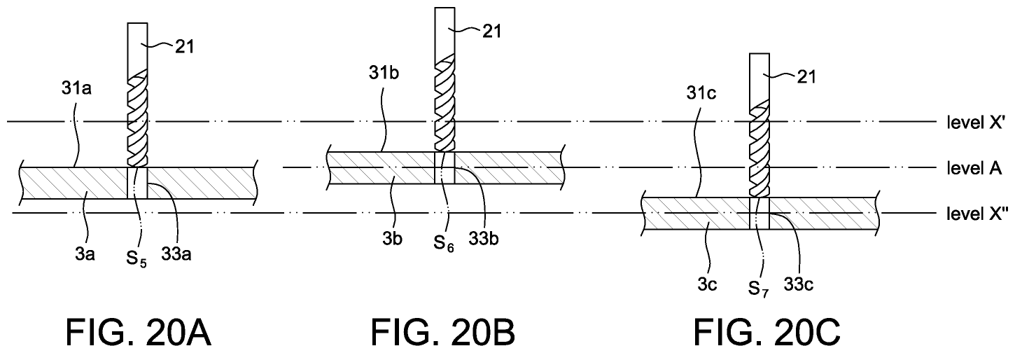

FIG. 20A illustrates a schematic view of a first operation situation of the drilling tool 21 according to some embodiments of the present disclosure. As shown in FIG. 20A, a level A represents a predetermined standard level or a desired elevation. A level X′ represents a level or an elevation higher than the level A. The difference (or distance) between the level X′ and the level A is an acceptable value. For example, the difference (or distance) between the level X′ and the level A may be predetermined as 5% of a thickness of a workpiece. The level X′ may be considered as a top limit of a tolerance or a deviation of the level A. Any level or elevation located in a range between the level X′ and the level A is still acceptable and is within specification. In addition, a level X″ represents a level or an elevation lower than the level A. The difference (or distance) between the level X″ and the level A is an acceptable value. For example, the difference (or distance) between the level X″ and the level A may be predetermined as 5% of a thickness of a workpiece. The level X″ may be considered as a bottom limit of the tolerance or the deviation of the level A. Any level or elevation located in a range between the level X″ and the level A is still acceptable and is within specification. In addition, any level or elevation located outside a range between the level X″ and the level X′ is unacceptable and is out of specification.

As shown in FIG. 20A, a segment 3a may have a top surface 31a. The segment 3a may be a portion of a workpiece. The drilling tool 21 may contact the top surface 31a of the segment 3a at a start point S₅. The elevation of the start point S₅ may be detected or determined by the method shown in FIG. 4, FIG. 17, FIG. 18 or FIG. 19, and may be recorded in the record unit 26. Then, a comparison result executed by the data processing unit 27 shows that the elevation of the start point S₅ is same as the elevation of the level A. Then, the drilling tool 21 may move downward to remove a portion of the segment 3a to form a hole 33a. The downward moving distance of the drilling tool 21 is also referred to as the drilling depth (or stroke). For example, the drilling depth (or stroke) of the drilling tool 21 may be a thickness of the segment 3a. For example, the drilling depth (or stroke) of the drilling tool 21 may be a depth of the hole 33a. In some embodiments, the downward moving distance or the drilling depth of the drilling tool 21 may be predetermined.

FIG. 20B illustrates a schematic view of a second operation situation of the drilling tool 21 according to some embodiments of the present disclosure. As shown in FIG. 20B, a segment 3b may have a top surface 31b. The segment 3b may be a portion of a workpiece. The drilling tool 21 may contact the top surface 31b of the segment 3b at a start point S₆. The elevation of the start point S₆ may be detected or determined by the method shown in FIG. 4, FIG. 17, FIG. 18 or FIG. 19, and may be recorded in the record unit 26. Then, a comparison result executed by the data processing unit 27 shows that the elevation of the start point S₆ is higher than the elevation of the level A and is lower than the level X′. That is, the tip of the drilling tool 21 contacts the segment 3b before the tip of the drilling tool 21 is lowered to or reaches to the level A. Further, the elevation of the start point S₆ is acceptable since it is located in the range between the level X′ and the level A. Then, the drilling tool 21 may move downward to remove a portion of the segment 3b to form a hole 33b. The downward moving distance of the drilling tool 21 is also referred to as the drilling depth (or stroke). For example, the drilling depth (or stroke) of the drilling tool 21 may be a thickness of the segment 3b. For example, the drilling depth (or stroke) of the drilling tool 21 may be a depth of the hole 33b. In some embodiments, the downward moving distance or the drilling depth of the drilling tool 21 may be predetermined. In some embodiments, the drilling depth of the drilling tool 21 in FIG. 20B may be equal to the drilling depth of the drilling tool 21 in FIG. 20A.

FIG. 20C illustrates a schematic view of a third operation situation of the drilling tool 21 according to some embodiments of the present disclosure. As shown in FIG. 20C, a segment 3c may have a top surface 31c. The segment 3c may be a portion of a workpiece. The drilling tool 21 may contact the top surface 31c of the segment 3c at a start point S₇. The elevation of the start point S₇ may be detected or determined by the method shown in FIG. 4, FIG. FIG. 18 or FIG. 19, and may be recorded in the record unit 26. Then, a comparison result executed by the data processing unit 27 shows that the elevation of the start point S₇ is lower than the elevation of the level A and is higher than the level X″. That is, the tip of the drilling tool 21 move beyond the level A to contact the segment 3c. Further, the elevation of the start point S₇ is acceptable since it is located in the range between the level X″ and the level A. Then, the drilling tool 21 may move downward to remove a portion of the segment 3c to form a hole 33c. The downward moving distance of the drilling tool 21 is also referred to as the drilling depth (or stroke). For example, the drilling depth (or stroke) of the drilling tool 21 may be a thickness of the segment 3c. For example, the drilling depth (or stroke) of the drilling tool 21 may be a depth of the hole 33c. In some embodiments, the downward moving distance or the drilling depth of the drilling tool 21 may be predetermined. In some embodiments, the drilling depth of the drilling tool 21 in FIG. 20C may be equal to the drilling depth of the drilling tool 21 in FIG. 20A.

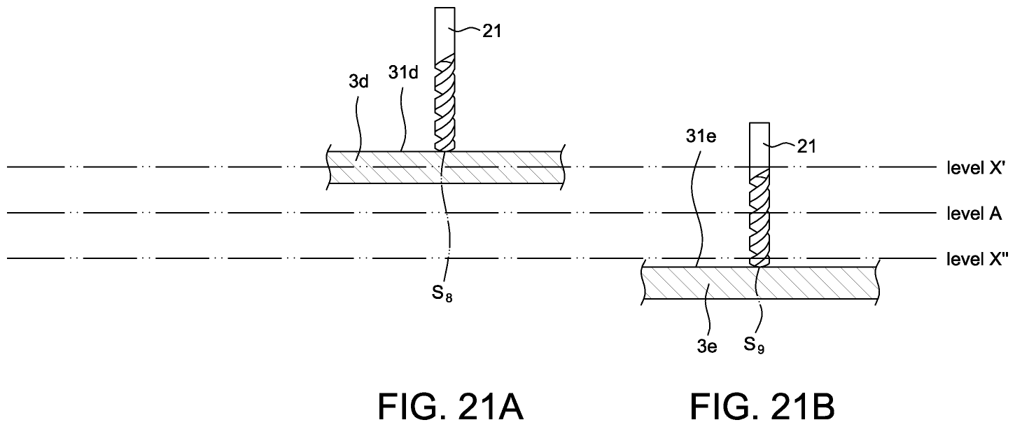

FIG. 21A illustrates a schematic view of a fourth operation situation of the drilling tool 21 according to some embodiments of the present disclosure. The level A, the level X′ and the level X″ of FIG. 21A are same as the level A, the level X′ and the level X″ of FIG. 20A, respectively. As shown in FIG. 21A, a segment 3d may have a top surface 31d. The segment 3d may be a portion of a workpiece. The drilling tool 21 may contact the top surface 31d of the segment 3d at a start point S₈. The elevation of the start point S₈ may be detected or determined by the method shown in FIG. 4, FIG. FIG. 18 or FIG. 19, and may be recorded in the record unit 26. Then, a comparison result executed by the data processing unit 27 shows that the elevation of the start point S₈ is higher than the elevation of the level X′. That is, the tip of the drilling tool 21 contacts the segment 3d before the tip of the drilling tool 21 is lowered to or reaches to the level X′. Further, the elevation of the start point S₈ is unacceptable and is out of specification since it is located outside the range between the level X″ and the level X′. Thus, the drilling tool 21 may not further move downward. The segment 3d may be not drilled at the start point S₈. In some embodiments, the data processing unit 27 may further generate an alarm signal to inform the operator. Such alarm signal may be recorded in the record unit 26.

FIG. 21B illustrates a schematic view of a fifth operation situation of the drilling tool 21 according to some embodiments of the present disclosure. As shown in FIG. 21B, a segment 3e may have a top surface 31e. The segment 3e may be a portion of a workpiece. The drilling tool 21 may contact the top surface 31e of the segment 3e at a start point S₉. The elevation of the start point S₉ may be detected or determined by the method shown in FIG. 4, FIG. FIG. 18 or FIG. 19, and may be recorded in the record unit 26. Then, a comparison result executed by the data processing unit 27 shows that the elevation of the start point S₉ is lower than the elevation of the level X″. That is, the tip of the drilling tool 21 move beyond the level X″ to contact the segment 3e. Further, the elevation of the start point S₉ is unacceptable and is out of specification since it is located outside the range between the level X″ and the level X′. Thus, the drilling tool 21 may not further move downward. The segment 3e may be not drilled at the start point S₉. In some embodiments, the data processing unit 27 may further generate an alarm signal to inform the operator. Such alarm signal may be recorded in the record unit 26.

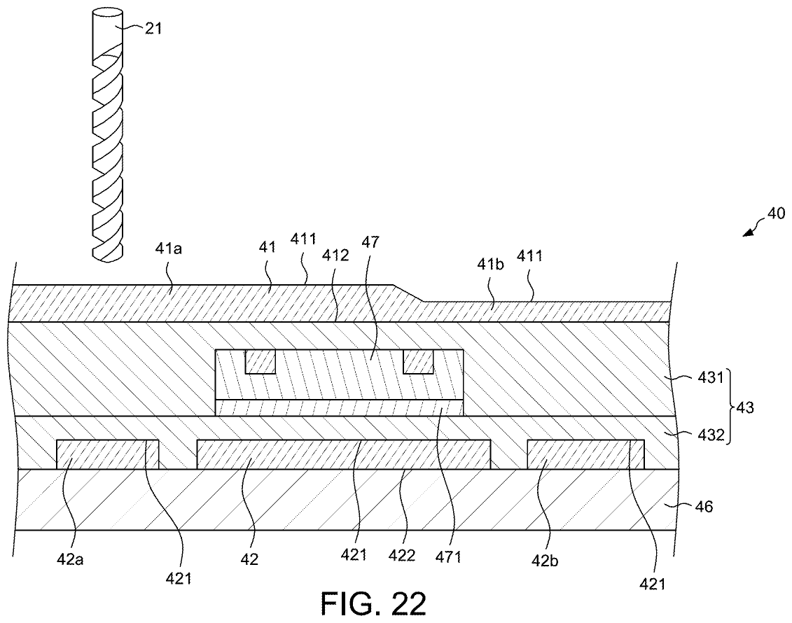

FIG. 22 through FIG. 29 illustrate a method for forming at least one conductive via in a workpiece 40 according to some embodiments of the present disclosure.

Referring to FIG. 22, a workpiece 40 is provided. The workpiece 40 may be, for example, a substrate (e.g., the substrate 10 of FIG. 2), a semiconductor package structure or a printed circuit board (PCB). The workpiece 40 may include a first conductive layer 41, a second conductive layer 42, a base layer 46, a dielectric structure 43 and an electronic device 47. The first conductive layer 41 may be, for example, a metal layer or a circuit layer. The first conductive layer 41 has a first conductive surface 411 and a second conductive surface 412 opposite to the first conductive surface 411. The first conductive surface 411 of the first conductive layer 41 may be a top surface of the workpiece 40. The first conductive layer 41 may include a first portion 41a and a second portion 41b. A thickness of the first portion 41a is greater than a thickness of the second portion 41b Thus, the first conductive layer 41 may have a non-uniform thickness or an inconsistent thickness. The first conductive surface 411 of the first conductive layer 41 may be an uneven surface.

The second conductive layer 42 may be longitudinally spaced apart from the first conductive layer 41. The second conductive layer 42 may be, for example, a metal layer or a circuit layer, and may be disposed on the base layer 46. The second conductive layer 42 has a first conductive surface 421 and a second conductive surface 422 opposite to the first conductive surface 421. The second conductive layer 42 may include a first portion 42a and a second portion 42b. The first portion 42a of the second conductive layer 42 may correspond to the first portion 41a of the first conductive layer 41. The second portion 42b of the second conductive layer 42 may correspond to the second portion 41b of the first conductive layer 41. A thickness of the first portion 42a of the second conductive layer 42 may be equal to or different from a thickness of a thickness of the second portion 42b of the second conductive layer 42.

The dielectric structure 43 may be disposed between the first conductive layer 41 and the base layer 46. In some embodiments, the dielectric structure 43 may include a first layer 431 and a second layer 432. The second layer 432 may be formed or disposed on the base layer 46 to cover the second conductive layer 42. The electronic device 47 may be attached to or adhered to the second layer 432 through an adhesion layer 471. The first layer 431 may be formed or disposed on the second layer 432 to cover the electronic device 47. The first conductive layer 41 may be formed or disposed on the first layer 431.

Then, a drilling tool 21 of a drilling device 20 (FIG. 2) may be disposed above the first portion 41a of the first conductive layer 41 of the workpiece 40. The first conductive element 231 (FIG. 2) of the drilling device 20 may contact or may be electrically connected to the first conductive surface 411 of the first conductive layer 41. The second conductive element 232 (FIG. 2) of the drilling device 20 may contact or may be electrically connected to the second conductive surface 422 of the second conductive layer 42.

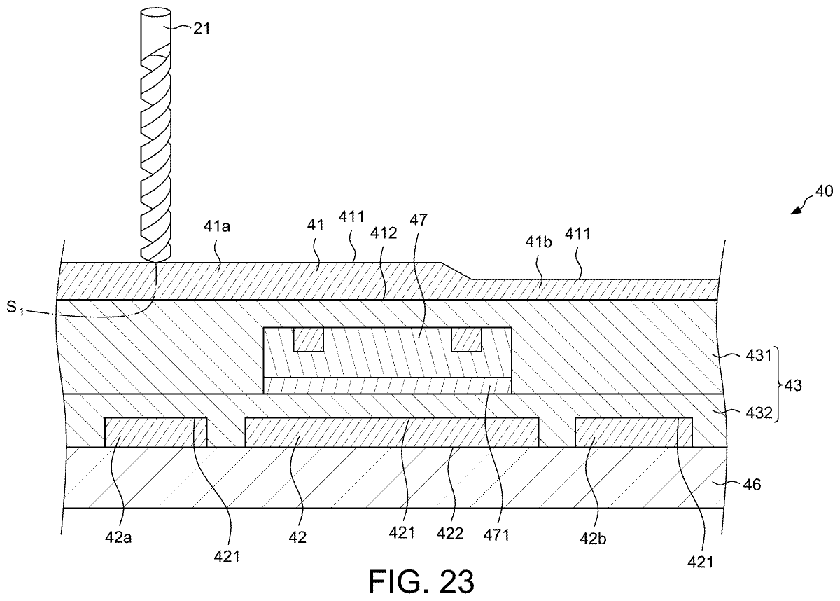

Referring to FIG. 23, the drilling tool 21 is moved to contact the workpiece 40. A first start point S₁ is defined through a first electric signal generated by the drilling tool 21 contacting the first conductive surface 411 of the first portion 41a of the first conductive layer 41. Meanwhile, a first electrical loop is formed through electrical connections of the drilling tool 21, the first conductive surface 411 of the first conductive layer 41, the first conductive element 231 (FIG. 2) and the current source 22 (FIG. 2). In some embodiments, the first electrical loop may generate the first electric signal. In some embodiments, when the first electrical loop and the first electric signal are generated, the drilling tool 21 starts to rotate so as to start the drilling process or drilling operation.

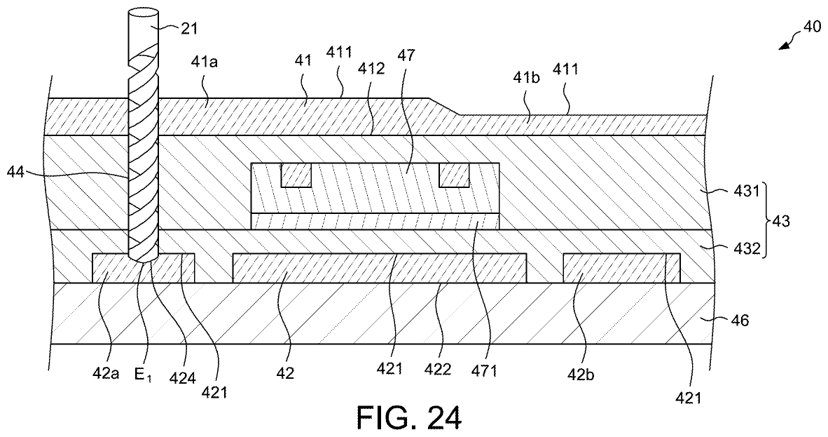

Referring to FIG. 24, the drilling tool 21 is moved downward to penetrate through the first conductive layer 41 and the dielectric structure 43, and contact the first conductive surface 421 of the first portion 42a of the second conductive layer 42. A first end point E₁ is defined through a second electric signal generated by the drilling tool 21 contacting the first conductive surface 421 of the first portion 42a of the second conductive layer 42. The first end point E₁ is located on the first conductive surface 421 of the first portion 42a of the second conductive layer 42. Meanwhile, a second electrical loop is formed through electrical connections of the drilling tool 21, the second conductive surface 422 of the second conductive layer 42, the second conductive element 232 (FIG. 2) and the current source 22 (FIG. 2). In some embodiments, the second electrical loop may generate the second electric signal. In addition, the second electric signal is generated after the first electric signal disappears. Thus, there is a time difference between the second electric signal and the first electric signal. In some embodiments, when the second electrical loop and the second electric signal are generated, the drilling tool 21 may stop to rotate so as to stop the drilling process or drilling operation. Thus, the drilling process or the drilling operation of the drilling tool 21 may stop at the first end point E₁ of second conductive layer 12.

In some embodiments, a first dimple 424 may be formed on the first conductive surface 421 of the second conductive layer 42. The first dimple 424 may be recessed from the first conductive surface 421 of the second conductive layer 42. The first end point E₁ may be a bottom end of the first dimple 424. In some embodiments, a first drilling depth (or stroke) of the drilling tool 21 may be determined according to a distance between the first start point S₁ and the first end point E₁.

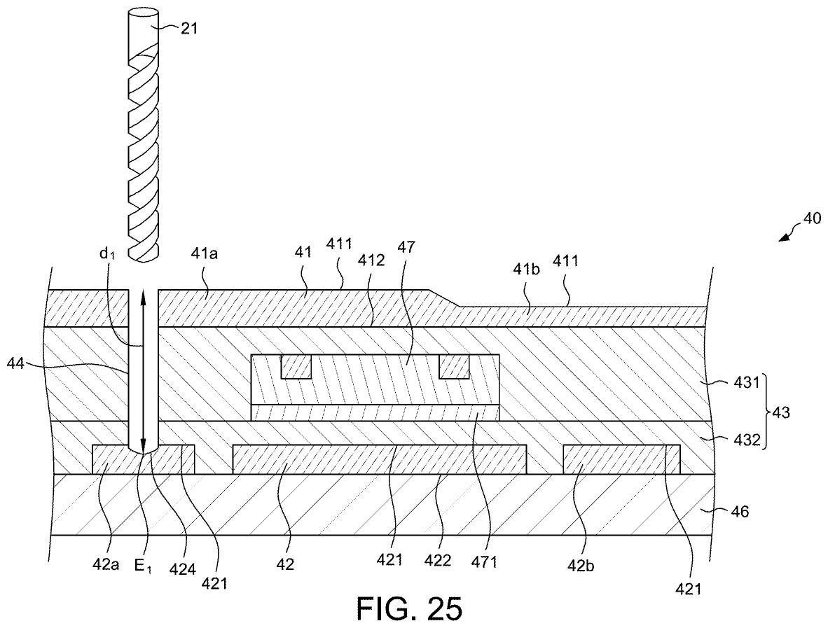

Referring to FIG. 25, the drilling device 20 is moved upward so that the drilling tool 21 is removed from the workpiece 40 so as to form a first hole 44 in the workpiece 40. The first hole 44 may stop at the first portion 42a of the second conductive layer 42. The first hole 44 may include the first dimple 424. The first hole 44 may be a blind hole that does not extend through the first portion 42a of the second conductive layer 42. The first hole 44 may have a first depth d₁. The first depth d₁ of the first hole 44 may be substantially equal to the first drilling depth (or stroke) of the drilling tool 21.

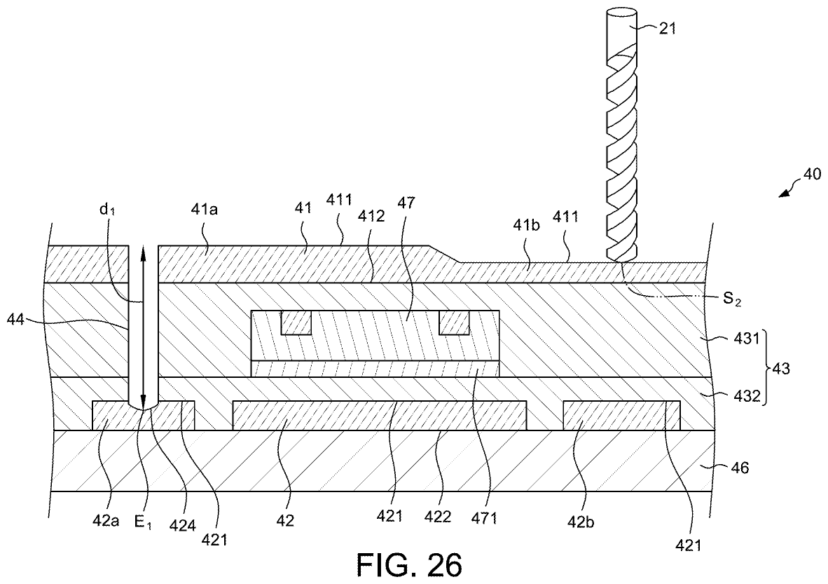

Referring to FIG. 26, the drilling device 20 and the drilling tool 21 are moved to a position above or corresponding to a second portion 41b of the workpiece 40. Then, the drilling tool 21 is moved downward to contact the workpiece 40. A second start point S₂ is defined through a third electric signal generated by the drilling tool 21 contacting the first conductive surface 411 of the first conductive layer 41. The elevation of the second start point S₂ may be lower than the elevation of the first start point S₁. Meanwhile, a third electrical loop is formed through electrical connections of the drilling tool 21, the first conductive surface 411 of the first conductive layer 41, the first conductive element 231 and the current source 22. In some embodiments, the third electrical loop may generate the third electric signal. In some embodiments, the third electrical loop and the third electric signal may be same as or similar to the first electrical loop and the first electric signal, respectively. In some embodiments, when the third electrical loop and the third electric signal are generated, the drilling tool 21 starts to rotate so as to start the drilling process or drilling operation.

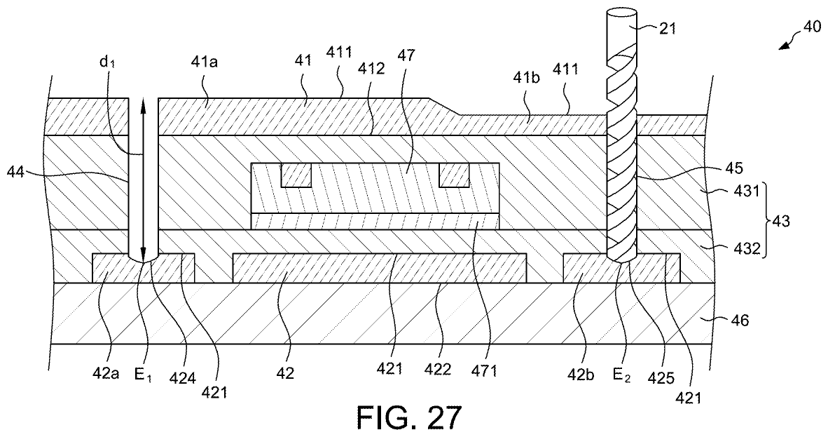

Referring to FIG. 27, the drilling tool 21 is moved downward to penetrate through the first conductive layer 41 and the dielectric structure 43. A second end point E₂ is defined through a fourth electric signal generated by the drilling tool 21 contacting the first conductive surface 421 of the second portion 42b of the second conductive layer 42. The second end point E₂ is located on the first conductive surface 421 of the second portion 42b of the second conductive layer 42. The elevation of the second end point E₂ may be same as or different form the elevation of the first end point E₁. Meanwhile, a fourth electrical loop is formed through electrical connections of the drilling tool 21, the first conductive surface 421 of the second conductive layer 42, the second conductive element 232 and the current source 22. In some embodiments, the fourth electrical loop may generate the fourth electric signal. In some embodiments, the fourth electrical loop and the fourth electric signal may be same as or similar to the second electrical loop and the second electric signal, respectively. In addition, the fourth electric signal is generated after the third electric signal disappears. Thus, there is a time difference between the fourth electric signal and the third electric signal. In some embodiments, when the fourth electrical loop and the fourth electric signal are generated, the drilling tool 21 may stop to rotate so as to stop the drilling process or drilling operation. Thus, the drilling process or the drilling operation of the drilling tool 21 may stop at the second end point E₂ of second conductive layer 42.

In some embodiments, a second dimple 425 may be formed on the first conductive surface 421 of the second portion 42b of the second conductive layer 42. The second dimple 425 may be recessed from the first conductive surface 421 of the second conductive layer 42. An elevation of the second dimple 425 may be same as or different from an elevation of the first dimple 424. In some embodiments, a second drilling depth (or stroke) of the drilling tool 21 may be determined according to a distance between the second start point S₂ and the second end point E₂.

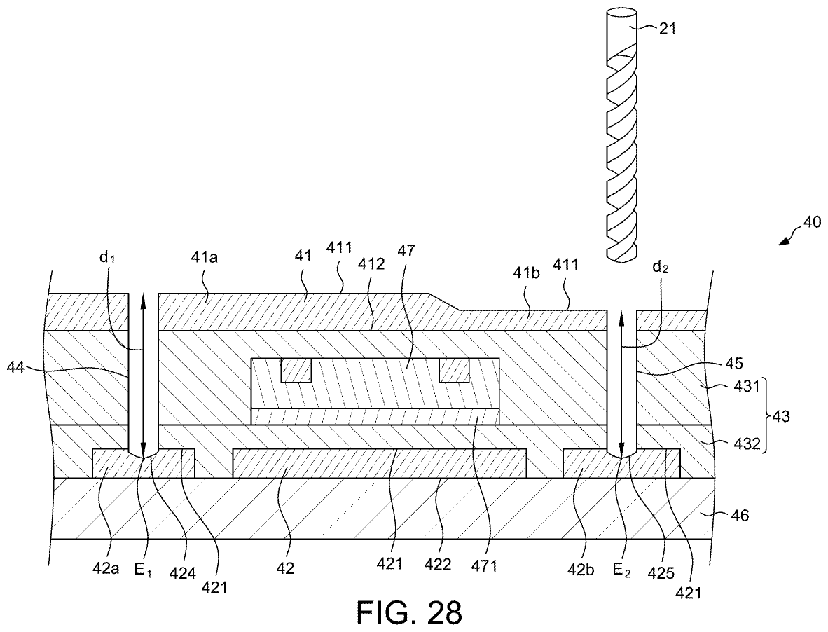

Referring to FIG. 28, the drilling tool 21 is removed from the workpiece 40 so as to form a second hole 45 in the workpiece 40. The second hole 45 may stop at the second conductive layer 22. The second hole 45 may include the second dimple 425. The second hole 45 may be a blind hole that does not extend through the second conductive layer 42. The second hole 45 may have a second depth d₂. In some embodiments, the second depth d₂ of the second hole 45 may be less than the first depth d₁ of the first hole 44.

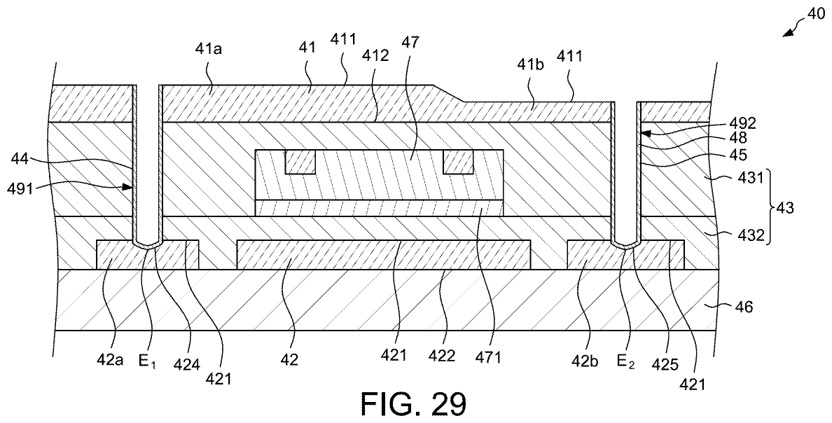

Referring to FIG. 29, a conductive material 48 (e.g., copper) may be formed on the sidewalls of the first hole 44 and the second hole 45 by, for example, deposition, coating or plating. For example, a first portion of the conductive material 48 may be formed on the sidewall of the first hole 44 so as to form a first conductive via 491 that electrically connects the first portion 41a of the first conductive layer 41 and the first portion 42a of the second conductive layer 42. A second portion of the conductive material 48 may be formed on the sidewall of the second hole 45 so as to form a second conductive via 492 that electrically connects the second portion 41b of the first conductive layer 41 and the second portion 42b of the second conductive layer 42. Since the first hole 44 and the second hole 45 may be formed precisely, the electrical connections between the first portion 41a of the first conductive layer 41 and the first portion 42a of the second conductive layer 42 and between the second portion 41b of the first conductive layer 41 and the second portion 42b of the second conductive layer 42 are ensured.

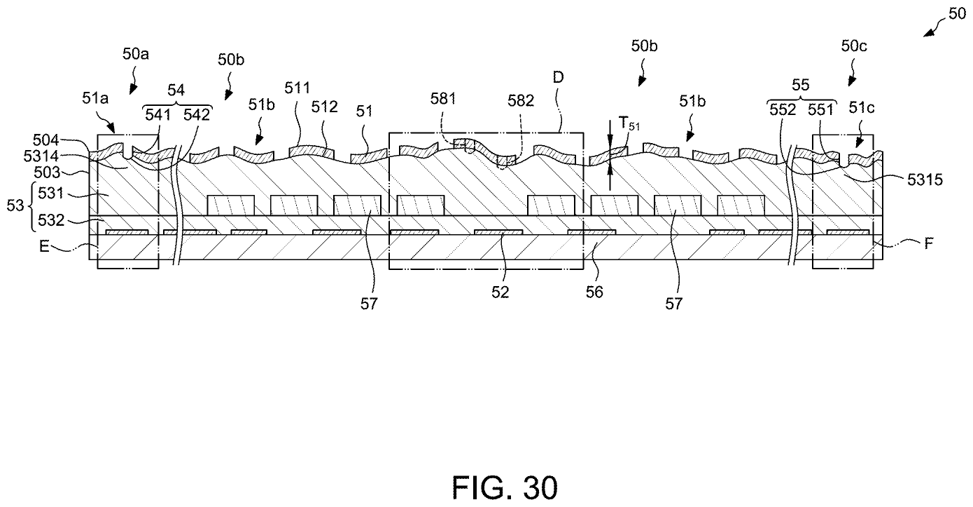

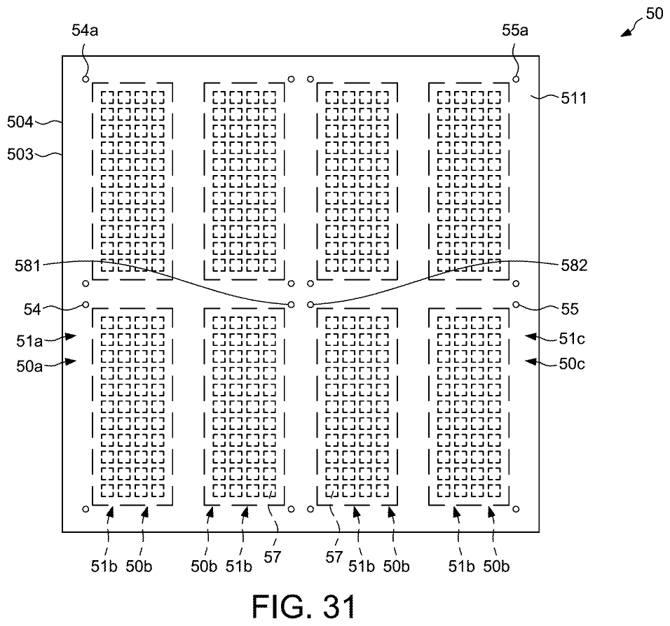

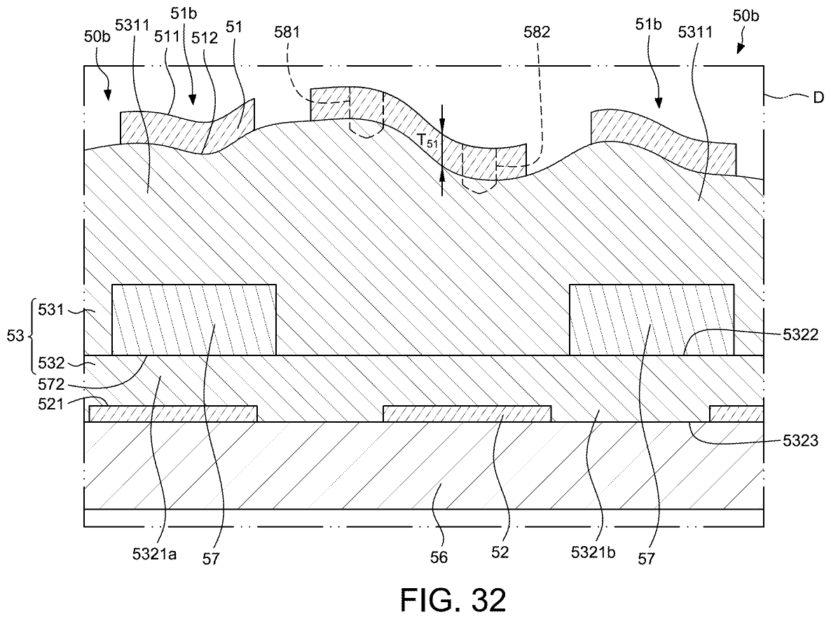

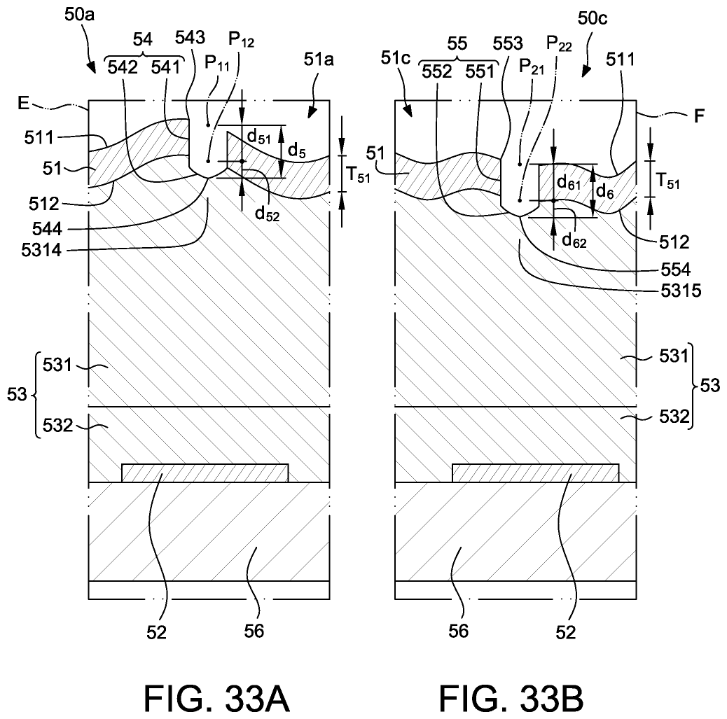

FIG. 30 illustrates a schematic view of a substrate 50 according to some embodiments of the present disclosure. FIG. 31 illustrates a top view of the substrate 50 of FIG. 30. FIG. 32 illustrates an enlarged view of a region “D” in FIG. 30. FIG. 33A illustrates an enlarged view of a region “E” in FIG. 30. FIG. 33B illustrates an enlarged view of a region “F” in FIG. 30.

The substrate 50 may be similar to the substrate 10 of FIG. 2 and the workpiece 40 of FIG. 22. The substrate 50 may include a first conductive layer 51, a second conductive layer 52, a base layer 56, a dielectric structure 53 and an electronic device 57. The first conductive layer 51 may be, for example, a metal layer or a circuit layer. The first conductive layer 51 has a first conductive surface 511 (e.g., a top surface) and a second conductive surface 512 (e.g., a bottom surface) opposite to the first conductive surface 511. The first conductive layer 51 may include a first portion 51a, a second portion 51b and a third portion 51c corresponding to a first portion 50a, a second portion 50b and a third portion 50c of the substrate 50, respectively. The second portion 51b may be a patterned circuit portion, a circuit region or an active area, and may be located on the second portion 50b of the substrate 50. The first portion 51a and the third portion 51c may be disposed around the second portion 51b. The first portion 51a and the third portion 51c may be dummy portions, non-circuit pattern regions, or non-circuit areas, and may be located on the first portion 50a and the third portion 50c of the substrate 50 respectively. The first conductive layer 51 may have a uniform thickness or a consistent thickness. The first conductive surface 511 and the second conductive surface 512 of the first conductive layer 51 may be uneven surfaces.

The second conductive layer 52 may be longitudinally spaced apart from the first conductive layer 51. The second conductive layer 52 may be, for example, a metal layer or a circuit layer, and may be disposed on the base layer 56. The dielectric structure 53 may be disposed between the first conductive layer 51 and the base layer 56. In some embodiments, the dielectric structure 53 may include a first layer 531 and a second layer 532. The first layer 531 may be a first dielectric layer, and the second layer 532 may be a second dielectric layer. The second layer 532 may be formed or disposed on the base layer 56 to cover the second conductive layer 52.

The electronic device 57 may be attached to or adhered to the second layer 532. The electronic device 57 may be located under the second portion 51b of the first conductive layer 51. There may be no electronic device 57 located under the first portion 51a and the third portion 51c. The first layer 531 may be formed or disposed on the second layer 532 to cover the electronic device 57. Thus, the electronic device 57 may be encapsulated by the dielectric structure 53.

As shown in FIG. 32, a thickness variation of a first portion 5311 of the first layer 531 of the dielectric structure 53 above the electronic device 57 is different from a thickness variation of a second portion 5321a, 5321b of the second layer 532 of the dielectric structure 53 under the electronic device 57. In some embodiments, the thickness variation of the first portion 5311 of the first layer 531 may be greater than the thickness variation of the second portion 5321a, 5321b of the second layer 532. The first conductive layer 51 may be stacked on the first layer 531 of the dielectric structure 53. As shown in FIG. 32, the second portion 5321a of the second layer 532 is the portion of the second layer 532 between a bottom surface 572 of the electronic device 57 and a top surface 521 of the second conductive layer 52. The top surface 521 of the second conductive layer 52 may be an interface between the second layer 532 and the second conductive layer 52. The second portion 5321b of the second layer 532 is the portion of the second layer 532 between a top surface 5322 of the second layer 532 and a bottom surface 5323 of the second layer 532. Alternatively, the second portion 5321b of the second layer 532 is the portion of the second layer 532 between the bottom surface 572 of the electronic device 57 and a top surface of the base layer 56. The top surface of the base layer 56 may be an interface between the second layer 532 and the base layer 56.

In some embodiments, the dielectric structure 53 may include at least one resin film. A material of the resin film may include epoxy and inorganic oxide powder or filler. The resin film may be free of fibers, and may include a jelly-like substance before being cured. Thus, the first layer 531 may be a resin film, and the second layer 532 may be also a resin film. A material of the first layer 531 may be same as or different from a material of the second layer 532.

As shown in FIG. 30, the substrate 50 may define a first hole 54 and a second hole 55 located on the first portion 51a or the third portion 51c of the first conductive layer 51. The first hole 54 may extend from the first conductive surface 511 (e.g., the top surface) of the first conductive layer 51 toward the dielectric structure 53. The first hole 54 may be recessed form the first conductive surface 511 (e.g., the top surface) of the first conductive layer 51, and may expose a first portion 5314 of the first layer 531 of the dielectric structure 53 so as to be detected or recognized by human eyes or a detector such as a charge coupled device (CCD). In addition, the second hole 55 may be spaced apart from the first hole 54, and may extend from the first conductive surface 511 (e.g., the top surface) of the first conductive layer 51 toward the dielectric structure 53. The second hole 55 may be recessed form the first conductive surface 511 (e.g., the top surface) of the first conductive layer 51, and may expose a second portion 5315 of the first layer 531 of the dielectric structure 53 so as to be detected or recognized by human eyes or a detector such as a charge coupled device (CCD).

As shown in FIG. 30 to FIG. 32, the substrate 50 may further define a third hole 581, a fourth hole 582, a fifth hole 54a and a sixth hole 55a. The shape and function of the third hole 581, the fourth hole 582, the fifth hole 54a and the sixth hole 55a may be same as or similar to the first hole 54 or the second hole 55. Thus, the third hole 581, the fourth hole 582, the fifth hole 54a and the sixth hole 55a may be recessed form the first conductive surface 511 (e.g., the top surface) of the first conductive layer 51, and may expose a portion of the first layer 531 of the dielectric structure 53 so as to be detected or recognized by human eyes or a detector such as a charge coupled device (CCD). The third hole 581 and the fourth hole 582 may be located at the position between the second portions 51b. The fifth hole 54a and the sixth hole 55a may be located at the corners of the substrate 50.

As shown in FIG. 33A and FIG. 33B, a first depth ds of the first hole 54 may be substantially equal to a second depth do of the second hole 55. An elevation of a topmost end 543 of the first hole 54 may be different from an elevation of a topmost end 553 of the second hole 55. For example, the elevation of the topmost end 543 of the first hole 54 may be higher than the elevation of the topmost end 553 of the second hole 55. In some embodiments, the first hole 54 may include a first portion 541 and second portion 542. The first portion 541 may be a through hole that extends through the first conductive layer 51, and may be in a cylinder shape. The first portion 541 may have a depth d₅₁. The second portion 542 may be a blind hole that is embedded in the first layer 531 of the dielectric structure 53, and may be communicated with the first portion 541. The second portion 542 may taper from the first conductive layer 51 toward the dielectric structure 53. The second portion 542 may have a depth d₅₂. In addition, the second hole 55 may include a first portion 551 and second portion 552. The first portion 551 may be a through hole that extends through the first conductive layer 51, and may be in a cylinder shape. The first portion 551 may have a depth d₆₁. The second portion 552 may be a blind hole that is embedded in the first layer 531 of the dielectric structure 53, and may be communicated with the first portion 551. The second portion 552 may taper from the first conductive layer 51 toward the dielectric structure 53. The second portion 552 may have a depth d₆₂. The depth d₅₁ of the first portion 541 of the first hole 54 may be substantially equal to a depth d₆₁ of the first portion 551 of the second hole 55. The depth d₅₂ of the second portion 542 of the second hole 55 may be substantially equal to a depth d₆₂ of the second portion 552 of the second hole 55. An elevation of a bottommost end 544 of the second portion 542 of the first hole 54 may be different from an elevation of a bottommost end 554 of the second portion 552 of the second hole 55.

The first hole 54 and the second hole 55 may be used as alignment marks that can be detected or recognized by human eyes or a detector such as a charge coupled device (CCD) above the substrate 50 during a manufacturing process. In some embodiments, the alignment mark(s) of a mask used in a patterning process may be aligned with the first hole 54 and/or the second hole 55 of the substrate 50.

As shown in FIG. 30 and FIG. 31, the substrate 50 may have a lateral surface 503 and an edge 504. The lateral surface 503 may extend between the top surface of the substrate 50 and the bottom surface of the substrate 50. The edge 504 may correspond to the lateral surface 503. The first portion 51a and the third portion 51c of the first conductive layer 51 are located adjacent to the lateral surface 503 or the edge 504. Thus, the first portion 51a and the third portion 51c of the first conductive layer 51 is closer to the lateral surface 503 or the edge 504 than the second portion 51b of the first conductive layer 51 is. In addition, the first portion 51a and the third portion 51c of the first conductive layer 51 is closer to the lateral surface 503 or the edge 504 than the electronic device 57 is. Thus, the first hole 54, the second hole 55, the fifth hole 54a and the sixth hole 55a are closer to the lateral surface 503 or the edge 504 than the electronic device 57 is.

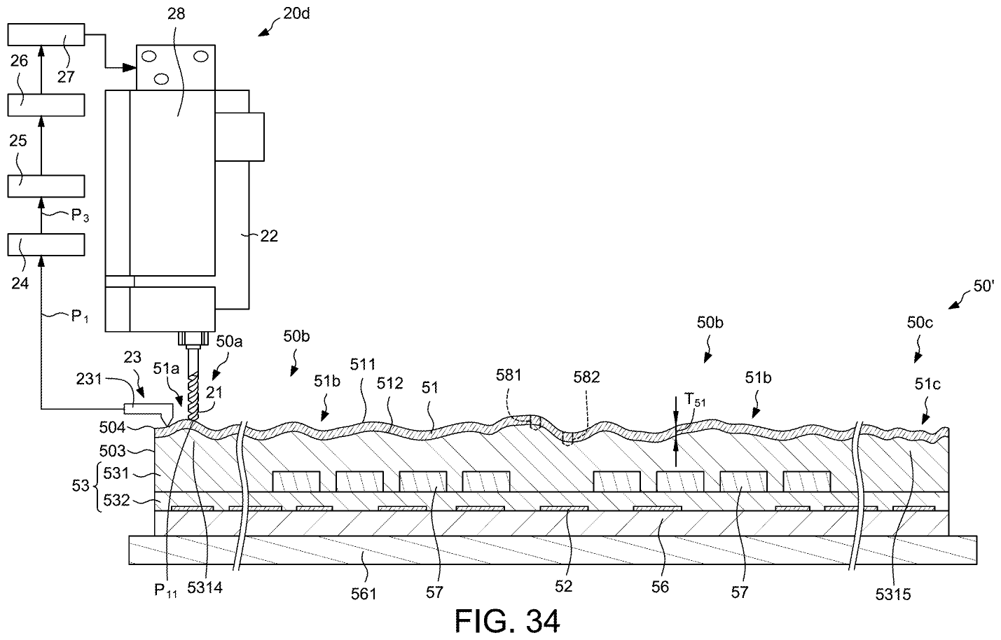

FIG. 34 through FIG. 39 illustrate a method for manufacturing a substrate according to some embodiments of the present disclosure. In some embodiments, the method is for manufacturing the substrate 50 shown in FIG. 30.

Referring to FIG. 34, a structure 50′ (or an assembly structure 50′) may be provided. The assembly structure 50′ may include a first conductive layer 51, a second conductive layer 52, a base layer 56, a dielectric structure 53, an electronic device 57 and a carrier 561. The first conductive layer 51, the second conductive layer 52, the base layer 56, the dielectric structure 53 and the electronic device 57 may be stacked on the carrier 561. Thus, the base layer 56 and the dielectric structure 53 may be disposed between the first conductive layer 51 and the carrier 561. For example, the carrier 561 may be a metal plate such as a steel plate or an aluminum plate. The first conductive layer 51 may be, for example, a metal layer. In some embodiments, the first conductive layer 51 may include conductive polymer such as polyacetylene. The first conductive layer 51 has a first conductive surface 511 (e.g., a top surface) and a second conductive surface 512 (e.g., a bottom surface) opposite to the first conductive surface 511. The first conductive layer 51 may include a first portion 51a, a second portion 51b and a third portion 51c. The first portion 51a and the third portion 51c may be disposed around the second portion 51b. The first conductive layer 51 may have a uniform thickness or a consistent thickness. The first conductive surface 511 and the second conductive surface 512 of the first conductive layer 51 may be uneven surfaces.

The second conductive layer 52 may be longitudinally spaced apart from the first conductive layer 51. The second conductive layer 52 may be disposed on the base layer 56. The dielectric structure 53 may be disposed between the first conductive layer 51 and the base layer 56. In some embodiments, the dielectric structure 53 may include a first layer 531 and a second layer 532. The first layer 531 may be a first dielectric layer, and the second layer 532 may be a second dielectric layer. The second layer 532 may be formed or disposed on the base layer 56 to cover the second conductive layer 52. The second conductive surface 512 (e.g., a bottom surface) of the first conductive layer 51 may face and contact the first layer 531 of the dielectric structure 53.

The electronic device 57 may be attached to or disposed on the second layer 532. The electronic device 57 may be located under the second portion 51b of the first conductive layer 51. The first layer 531 may be formed or disposed on the second layer 532 to cover the electronic device 57. Thus, the electronic device 57 may be encapsulated by the dielectric structure 53.

A drilling device 20d may be provided. The drilling device 20d of FIG. 34 may be same as or similar to the drilling device 20 of FIG. 1 to FIG. 4. The drilling tool 21 of the drilling device 20d is moved to contact the first conductive surface 511 (e.g., the top surface) of the first conductive layer 51 of the assembly structure 50′ so as to detect the first conductive surface 511 (e.g., the top surface) of the first conductive layer 51 of the assembly structure 50′. A first start point Pu is defined through a first electric signal generated by the drilling tool 21 contacting the first conductive surface 511 of the first conductive layer 51. The first start point Pu of the first conductive surface 511 (e.g., the top surface) may be selected or predetermined when the drilling tool 21 contacts the first conductive surface 511 (e.g., the top surface). The first start point P₁₁ is located outside the second portion 51b (e.g., the patterned circuit portion) of the first conductive layer 51 of FIG. 30. Meanwhile, a first electrical loop is formed through electrical connections of the drilling tool 21, the first conductive surface 511 of the first conductive layer 51, the first conductive element 231 and the current source 22. In some embodiments, the first electrical loop may generate the first electric signal. In some embodiments, the top surface 511 of the first conductive layer 51 is determined or detected when the drilling tool 21 contacts the first conductive layer 51 at the first start point P₁₁. In some embodiments, when the first electrical loop and the first electric signal are generated, the drilling tool 21 starts to rotate so as to start the drilling process or drilling operation.

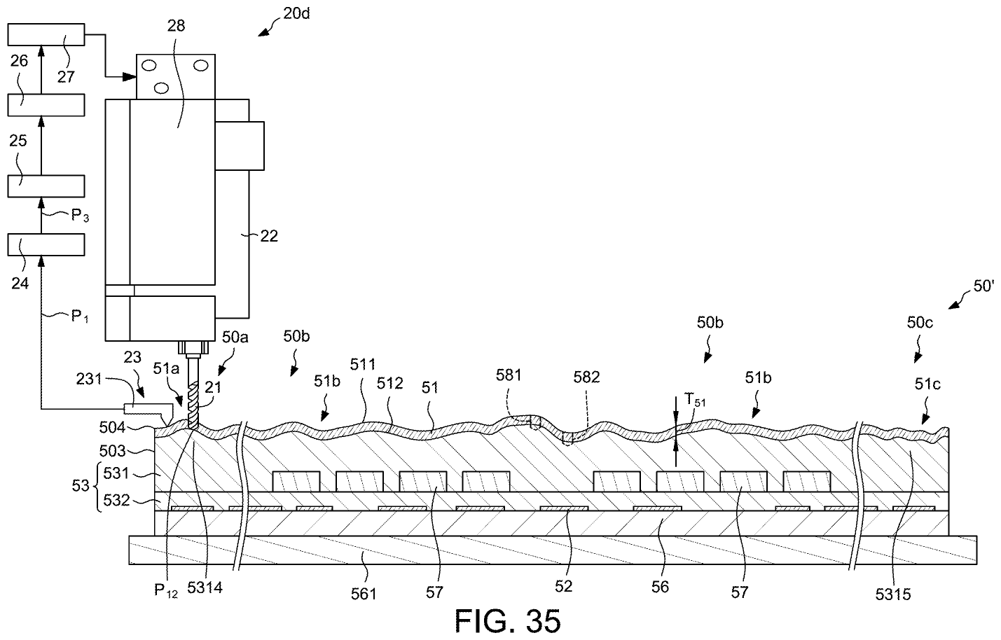

Referring to FIG. 35, the drilling tool 21 is moved downward to drill the detected top surface 511 of the first conductive layer 51 at the first start point P₁₁ by a first predetermined distance until the drilling tool 21 reaches a first lower point P₁₂ on the bottom surface 512 of the first conductive layer 51. Thus, the first predetermined distance may be a distance between the first start point Pu and the first lower point P₁₂, and may be equal to the depth d₅₁ of the first portion 541 of the first hole 54 of FIG. 33A or equal to a thickness T₅₁ of the first conductive layer 51. That is, the assembly structure 50′ is drilled since the top surface 511 toward the first layer 531 of the dielectric structure 53 by the first predetermined distance no less than the thickness T₅₁ of the first conductive layer 51 to form an alignment mark (e.g., the first hole 54 of FIG. 30). Meanwhile, the drilling tool 21 penetrates through the first conductive layer 51, and a first drilling depth in the first conductive layer 51 may be equal to the first predetermined distance (e.g., the depth d₅₁ of the first portion 541 of the first hole 54).

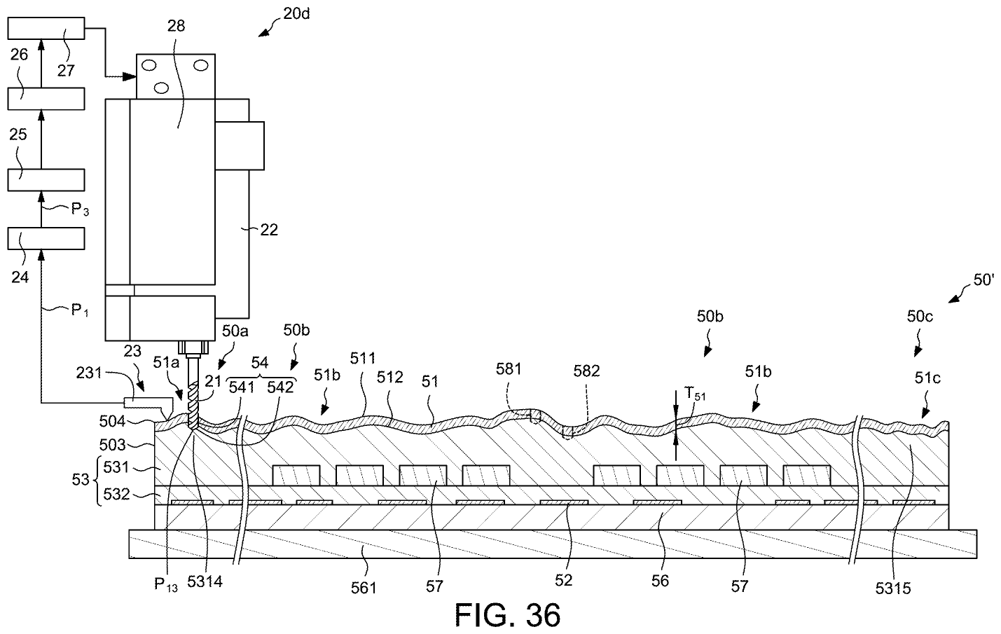

Referring to FIG. 36, the drilling tool 21 is further moved downward to drill the first layer 531 (e.g., the first dielectric layer) of the dielectric structure 53 after the drilling tool 21 passes through the first conductive layer 51. The drilling tool 21 may further moved downward by a second predetermined distance until the drilling tool 21 reaches a first end point P₁₃ in the first layer 531 (e.g., the first dielectric layer) of the dielectric structure 53. Thus, the second predetermined distance may be a distance between the first lower point P₁₂ and the first end point P₁₃, and may be equal to the depth d₅₂ of the second portion 542 of the first hole 54 of FIG. 33A. Meanwhile, the drilling tool 21 does not penetrates through the first layer 531 (e.g., the first dielectric layer) of the dielectric structure 53. The first hole 54 of FIG. 33A may be formed. The first end point P₁₃ is the bottommost end 544 of the second portion 542 of the first hole 54 of FIG. 33A. A second drilling depth (or a depth) in the first layer 531 (e.g., the first dielectric layer) of the dielectric structure 53 may be equal to the second predetermined distance (e.g., the depth d₅₂ of the second portion 542 of the first hole 54). That is, the drilling tool 21 may drill the first layer 531 (e.g., the first dielectric layer) of the dielectric structure 53 with the second drilling depth therein. The second drilling depth (e.g., the depth d₅₂ of the second portion 542 of the first hole 54) in the first layer 531 may be less than the first drilling depth in the first conductive layer 51 (e.g., the depth d₅₁ of the first portion 541 of the first hole 54). Alternatively, the second drilling depth in the first layer 531 may be less than the thickness T₅₁ of the first conductive layer 51.

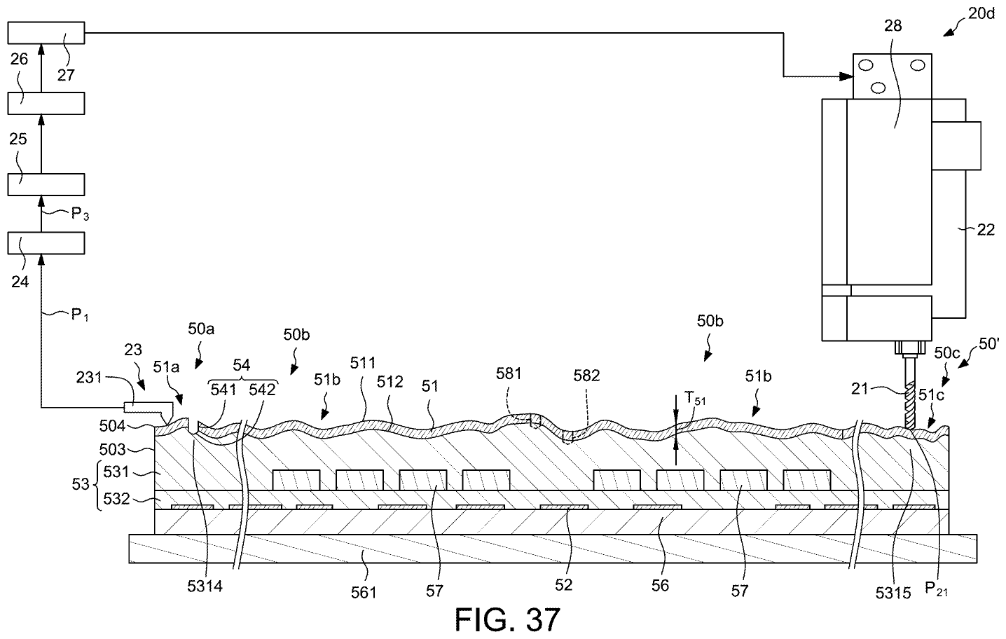

Referring to FIG. 37, the drilling device 20d and the drilling tool 21 are moved away from the first hole 54. Then, the drilling tool 21 of the drilling device 20d is moved to contact the first conductive surface 511 (e.g., the top surface) of the first conductive layer 51 of the assembly structure 50′ so as to detect the first conductive surface 511 (e.g., the top surface) of the first conductive layer 51 of the assembly structure 50′. A second start point P₂₁ is defined through a second electric signal generated by the drilling tool 21 contacting the first conductive surface 511 of the first conductive layer 51. The second start point P₂₁ of the first conductive surface 511 (e.g., the top surface) may be selected or predetermined when the drilling tool 21 contacts the first conductive surface 511 (e.g., the top surface). The second start point P₂₁ is located outside the second portion 51b (e.g., the patterned circuit portion) of the first conductive layer 51 of FIG. 30. An elevation of the first start point Pu is different from an elevation of the second start point P₂₁. That is, the second start point P₂₁ is not level with the first start point P₁₁. Meanwhile, a second electrical loop is formed through electrical connections of the drilling tool 21, the first conductive surface 511 of the first conductive layer 51, the first conductive element 231 and the current source 22. In some embodiments, the second electrical loop may generate the second electric signal. In some embodiments, the top surface 511 of the first conductive layer 51 is determined or detected when the drilling tool 21 contacts the first conductive layer 51 at the second start point P₂₁. In some embodiments, when the second electrical loop and the second electric signal are generated, the drilling tool 21 starts to rotate so as to start the drilling process or drilling operation.

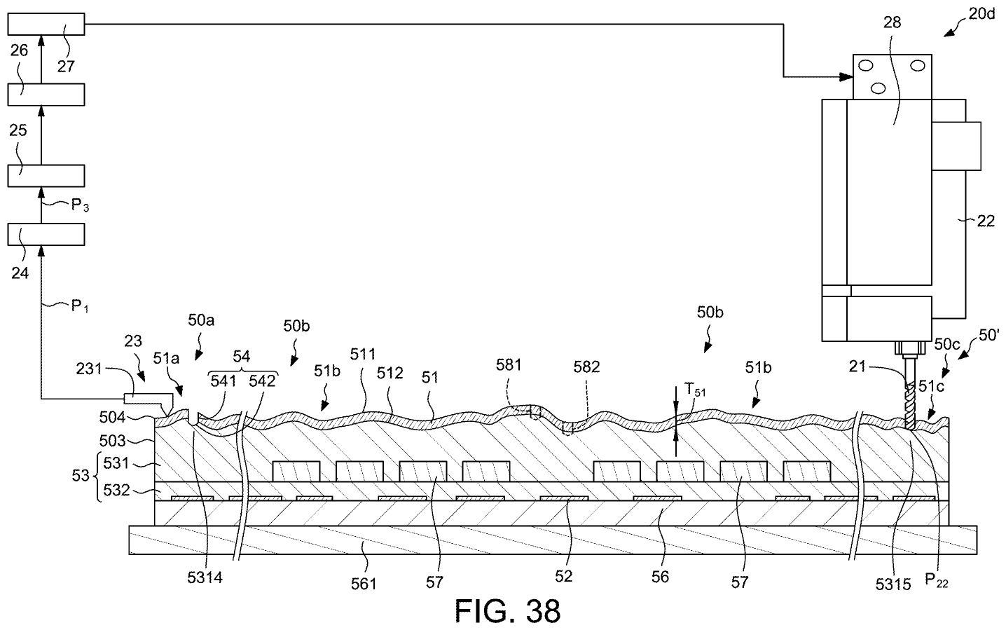

Referring to FIG. 38, the drilling tool 21 is moved downward to drill the detected top surface 511 of first conductive layer 51 at the second start point P₂₁ by a third predetermined distance until the drilling tool 21 reaches a second lower point P₂₂ on the bottom surface 512 of the first conductive layer 51. Thus, the third predetermined distance may be a distance between the second start point P₂₁ and the second lower point P₂₂, and may be equal to the depth d₆₁ of the first portion 551 of the second hole 55 of FIG. 33B or equal to a thickness T₅₁ of the first conductive layer 51. That is, the assembly structure 50′ is drilled since the top surface 511 toward the first layer 531 of the dielectric structure 53 by the third predetermined distance no less than the thickness T₅₁ of the first conductive layer 51 to form an alignment mark (e.g., the second hole 55 of FIG. 30). Meanwhile, the drilling tool 21 penetrates through the first conductive layer 51, and a third drilling depth in the first conductive layer 51 may be equal to the third predetermined distance (e.g., the depth d₆₁ of the first portion 551 of the second hole 55). In addition, the third predetermined distance (e.g., the depth d₆₁ of the first portion 551 of the second hole 55) may be substantially equal to the first predetermined distance (e.g., the depth d₅₁ of the first portion 541 of the first hole 54).

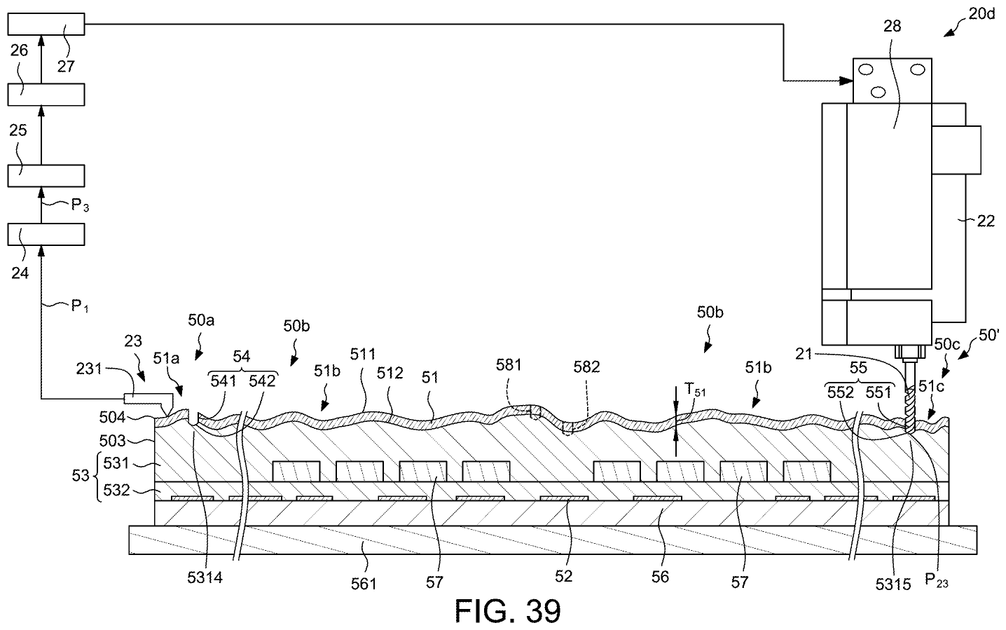

Referring to FIG. 39, the drilling tool 21 is further moved downward to drill the first layer 531 (e.g., the first dielectric layer) of the dielectric structure 53 after the drilling tool 21 passes through the first conductive layer 51. The drilling tool 21 may further moved downward by a fourth predetermined distance until the drilling tool 21 reaches a second end point P₂₃ in the first layer 531 (e.g., the first dielectric layer) of the dielectric structure 53. Thus, the fourth predetermined distance may be a distance between the second lower point P₂₂ and the second end point P₂₃, and may be equal to the depth d₆₂ of the second portion 552 of the second hole 55 of FIG. 33B. Meanwhile, the drilling tool 21 does not penetrates through the first layer 531 (e.g., the first dielectric layer) of the dielectric structure 53. The second hole 55 of FIG. 33A may be formed. The second end point P₂₃ is the bottommost end 554 of the second portion 552 of the second hole 55 of FIG. 33B. A fourth drilling depth in the first layer 531 (e.g., the first dielectric layer) of the dielectric structure 53 may be equal to the fourth predetermined distance (e.g., the depth d₆₂ of the second portion 552 of the second hole 55).

Then, the second portion 51b of the first conductive layer 51 may be patterned to form a circuit layer according to the alignment marks (e.g., the first hole 54 and the second hole 55). Thus, the second portion 51b of the first conductive layer 51 may be a circuit region. That is, at least a portion of the first conductive layer 51 disposed in the second portion 50b of the substrate 50 may be patterned to form a circuit region. In some embodiments, the alignment mark(s) of a mask used in the patterning process may be aligned with the alignment marks (e.g., the first hole 54 and the second hole 55) the assembly structure 50′.

Then, the carrier 561 may be removed from the assembly structure 50′ so as to form the substrate 50 of FIG. 30.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3º, less than or equal to ±2°, less than or equal to ±1°, less than or equal to ±0.5°, less than or equal to ±0.1°, or less than or equal to ±0.05°. For example, a characteristic or quantity can be deemed to be “substantially” consistent if a maximum numerical value of the characteristic or quantity is within a range of variation of less than or equal to +10% of a minimum numerical value of the characteristic or quantity, such as less than or equal to +5%, less than or equal to +4%, less than or equal to +3%, less than or equal to +2%, less than or equal to +1%, less than or equal to +0.5%, less than or equal to +0.1%, or less than or equal to +0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method for manufacturing a substrate, comprising:
providing a carrier with a dielectric layer and a conductive layer stacked thereon, wherein the conductive layer has a bottom surface facing the dielectric layer and a top surface;
detecting the top surface of the conductive layer; and
drilling since the top surface toward the dielectric layer by a predetermined distance no less than a thickness of the conductive layer.

2. The method of claim 1, further comprising:
drilling into the dielectric layer with a depth therein.

3. The method of claim 2, wherein the depth in the dielectric layer is less than the thickness of the conductive layer.

4. The method of claim 1, further comprising:
determining a first start point of the top surface of the conductive layer when a drilling tool contacts the top surface; and
determining a second start point of the top surface of the conductive layer when the drilling tool contacts the conductive layer again; wherein the second start point is not level with the first start point.

5. The method of claim 4, further comprising:
drilling since the first start point toward the dielectric layer by a first predetermined distance no less than the thickness of the conductive layer; and
drilling since the second start point toward the dielectric layer by a second predetermined distance no less than the thickness of the conductive layer and substantially equal to the first predetermined distance.

6. The method of claim 1, wherein drilling since the top surface toward the dielectric layer includes drilling since the top surface toward the dielectric layer to form an alignment mark.

7. The method of claim 6, further comprising:
patterning at least a portion of the conductive layer according to the alignment mark.

8. A method for manufacturing a substrate, comprising:
providing a structure including a first conductive layer and a second conductive layer under the first conductive layer;
contacting a top surface of the first conductive layer with a drilling tool to determine a first start point;
drilling since the first start point;
contacting a top surface of the second conductive layer with the drilling tool to determine a first end point; and
stopping drilling after determining the first end point.

9. The method of claim 8, further comprising receiving a first signal when the drilling tool contacts the first conductive layer to determine the first start point.

10. The method of claim 9, wherein further comprising receiving a second signal when the drilling tool contacts the second conductive layer to determine the first end point.

11. The method of claim 8, further comprising:
forming a first electrical loop when the drilling tool contacts the first conductive layer or forming a second electrical loop when the drilling tool contacts the second conductive layer.

12. The method of claim 8, further comprising:
contacting the top surface of the first conductive layer with a drilling tool to determine a second start point;
drilling since the second start point;
contacting the top surface of the second conductive layer with the drilling tool to determine a second end point; and
stopping drilling after determining the second end point, wherein an elevation of the first start point is different from an elevation of the second start point.

13. The method of claim 12, further comprising:
estimating a flatness of the structure from a variation between the elevation of the first start point and the elevation of the second start point.

14. A substrate, comprising:
a dielectric structure;
a conductive layer stacked on the dielectric structure;
a first hole extending from a top surface of the conductive layer and exposing the dielectric structure; and
a second hole spaced apart from the first hole, and extending from the top surface of the conductive layer and exposing the dielectric structure,
wherein a first depth of the first hole is substantially equal to a second depth of the second hole, and an elevation of a topmost end of the first hole is different from an elevation of a topmost end of the second hole.

15. The substrate of claim 14, wherein the first hole includes a first portion extending through the conductive layer.

16. The substrate of claim 15, wherein the first hole further includes a second portion embedded in the dielectric structure and communicated with the first portion.

17. The substrate of claim 16, wherein the second hole includes a second portion embedded in the dielectric structure, and an elevation of a bottommost end of the second portion of the first hole is different from an elevation of a bottommost end of the second portion of the second hole.

18. The substrate of claim 14, further comprising:
an electronic device encapsulated by the dielectric structure, wherein a thickness variation of a first portion of the dielectric structure above the electronic device is greater from a thickness variation of a second portion of the dielectric structure under the electronic device.

19. The substrate of claim 18, wherein the dielectric structure includes a resin film.

20. The substrate of claim 14, wherein the first hole and the second hole are used as alignment marks.
